(19) United States
(12) Patent Application Publication
(10) Pub. No.: US 2010/0037121 A1
(43) Pub. Date: Feb. 11, 2010

(54) LOW POWER LAYERED DECODING FOR LOW DENSITY PARITY CHECK DECODERS

(75) Inventors: Jie Jin, Hong Kong (CN); Chi Ying Tsui, Hong Kong (CN)

Correspondence Address: TUROCY & WATSON, LLP, 127 Public Square, 57th Floor, Key Tower, CLEVELAND, OH, 44114, US

(73) Assignee: THE HONG KONG UNIVERSITY OF SCIENCE AND TECHNOLOGY, Hong Kong (CN)

(21) Appl. No.: 12/185,987

(22) Filed: Aug. 5, 2008

(51) Int. Cl. G11C 29/04; G06F 11/08; G06F 13/00; G06F 12/00

(52) U.S. Cl. 714/763; 711/154; 714/E11.03; 711/E12.001

(57) ABSTRACT

The disclosed subject matter provides low power layered LDPC decoders and related systems and methods. Exemplary embodiments of the disclosed subject matter can achieve significant reduction in memory access of the associated memories by bypassing the associated memories depending on the decoding algorithm (e.g., code rate) and the characteristic of the LDPC parity check matrix, thereby providing significant reductions power consumption of LDPC decoders. According to various embodiment, an optimal decoding order can be determined and scheduled to maximize the power reduction available by bypassing the associated memories. In addition, various algorithms are disclosed that determine optimal search orders under various constraints. According to the disclosed subject matter, particular embodiments can further reduce power consumption by employing the disclosed thresholding to further reduce memory access. Additionally, various modifications are provided, which achieve a wide range of performance and computational overhead trade-offs according to system design considerations.

### TECHNICAL FIELD

The subject disclosure relates to decoding algorithms and more specifically to low power layered decoding for low density parity check (LDPC) decoders.

### BACKGROUND

Recently, low-density parity-check (LDPC) codes have gained significant attention due to their near Shannon limit performance. For example, LDPC codes have been adopted in several wireless standards, such as Digital Video Broadcasting-Satellite-Second Generation (DVB-S2), Institute of Electrical and Electronics Engineers (IEEE) 802.16e and IEEE 802.11n, because of their excellent error correcting performance.

For example, FIG. 1 depicts a sparse parity check matrix H 102 representing a linear block code (e.g., a LDPC code). As can be appreciated, it can also be efficiently represented as a bipartite graph, also called a Tanner Graph 104 as shown, which can comprise two sets of nodes. For example, variable nodes 106 can represent the bits of a codeword, and check nodes 108 can implement parity-check constraints. Conventionally, a standard decoding procedure, a message passing algorithm (also known as “sum-product” or “belief propagation” (BP) Algorithm), can iteratively exchange messages between the check nodes 108 and the variable nodes 106 along the edges 110 of the graph 104.

For instance, in the original message passing algorithm, messages first are broadcasted to all check nodes 108 from variable nodes 106. Then along edges 110 of the graph 104 the updated messages are fed back from check nodes 108 to variable nodes 106 to finish one iteration of decoding. In order to achieve higher convergence speed, and thus minimize the number of decoding iteration, a serial message passing algorithm, also known as a layered decoding algorithm, can be used.

Accordingly, two types of layered decoding schemes can be used to achieve higher convergence speed (e.g., vertical layered decoding and horizontal layered decoding). In the horizontal layered decoding, a single or a certain number of check nodes 108 (also referred to as a “layer”) can be updated first. Then, the set of neighboring variable nodes 106 (e.g., the whole set of neighboring variable nodes 106) can be updated. Thereafter, the decoding process can proceed layer after layer. Horizontal layered decoding is typically preferable for practical implementations, because, as should be appreciated, a serial check node processor can be more easily implemented in Very-Large-Scale Integration (VLSI).

Furthermore, based on the number of processing units to be implemented, the LDPC decoder architecture can be further classified into three types (e.g., fully parallel architecture, serial architecture, and partially parallel architecture). For example, in fully parallel architecture implementations, a check node processor is typically needed for every check node, which can result in large hardware costs and less flexibility. Conversely, a serial architecture implementation can use just one check node processor to share the computation of all the check nodes 108. However, serial architecture implementations can be too slow for many applications.

Advantageously, partially parallel architecture implementations can use multiple processing units, which allow various design tradeoffs between hardware costs and required throughput. As a result, partially parallel architectures are more commonly adopted in actual implementations. However, while partially parallel architectures based on layered decoding algorithms can efficiently reduce hardware costs and speed up convergence rate, high power consumption of the LDPC decoder is still a challenging design problem.

Various algorithms such as the Min-sum decoding algorithm and its variants have been proposed to reduce the memory storage required for check node 108 to variable node 106 messages and reduce power consumption of the associated memories of the LDPC decoder with insignificant performance loss. However, it can be shown that power consumption of the associated memories can still account for more than half of the total power consumption of the decoder, due to the large amount of data access in every clock cycle. Accordingly, further work is required to implement low power LDPC decoder techniques that can reduce hardware costs while speeding up convergence rate.

The above-described deficiencies are merely intended to provide an overview of some of the problems encountered in LDPC decoder designs, and are not intended to be exhaustive. Other problems with the state of the art may become further apparent upon review of the description of the various non-limiting embodiments of the disclosed subject matter that follows.

### SUMMARY

In consideration of the above-described deficiencies of the state of the art, the disclosed subject matter provides decoder designs, related systems, and methods that can perform layered LDPC decoding while bypassing associated memories depending on the code rate and the parity matrix of the LDPC code to reduce power consumption of the decoder. According to further non-limiting embodiments, the disclosed subject matter provides further power reductions by employing the disclosed thresholding to further reduce decoder memory access operations.

The exemplary non-limiting embodiments of the disclosed subject matter facilitate reducing the amount of memory access, by utilizing existing or scheduled column overlapping of the LDPC parity check matrix, which is shown to minimize the amount of memory access for storing posterior values. In addition, the disclosed thresholding techniques further reduce the memory access (and thus power consumption) by utilizing carefully trading off error correcting performance. Exemplary embodiments of the disclosed subject matter provides decoders implemented in a Taiwan Semiconductor Manufacturing Company (TSMC®) 0.18 μm Complementary Metal-Oxide-Semiconductor (CMOS) process. Experimental results show that for a LDPC decoder targeting for IEEE 802.11n, the power consumption of the memory and the decoder can be reduced by 72% and 24%, respectively.

According to various non-limiting embodiments, the disclosed subject matter provides low power layered decoding systems and methods for LDPC decoders. According to further non-limiting embodiments, the disclosed subject matter provides decoding methods for a layered decoder. The decoding methods can comprise determining whether a current and a next layer have an overlapped column, and/or computing and scheduling an optimal decoding order for the layer. Thus, the methods can comprise bypassing a memory write and memory read operation that have a current and a next layer with an overlapped column. As a result, the provided architectures advantageously reduce the memory access operations resulting in significant power reduction.

Additionally, according to further non-limiting embodiments, the disclosed subject matter provides decoding systems comprising a Channel Random Access Memory (RAM) that can store soft output values of a variable node 106 of a current layer of two consecutive decoding layers. The systems can further comprise a memory bypass component that can bypass a memory write operation and a memory read operation for the channel RAM to directly the pass soft output values of the variable node 106 when the two consecutive layers in a layered decoder have overlapping columns. In addition, the systems can include a soft-input-soft-output (SISO) unit that can compute a two-output approximation of a check node 108 for a next layer of the two consecutive layers based on either the soft output values stored in the channel RAM or the soft output values directly passed by the memory bypass component. The decoding systems can further comprise a thresholding component that can determine whether the soft output values exceed a preset threshold and that replaces the soft output values with the preset threshold prior to storage in the channel RAM if the soft output values exceed the preset threshold.

In a further aspect of the disclosed subject matter, exemplary non-limiting embodiments of a layered decoding apparatus is provided that can comprise a channel Random Access Memory (RAM) that can store soft output values of a variable node 106 of a current layer of two consecutive layers. In addition, the decoding apparatus can comprise a plurality of pipeline registers coupled to an Add-array to facilitate bypassing the channel RAM read and write operations. The decoding apparatus can further include a plurality of multiplexers that selects and passes the output of the Add-array and an output of the channel RAM based on whether the channel RAM read and write operations are to be bypassed. In addition, the decoding apparatus can include a threshold memory that stores a bit when the soft output values exceed a threshold value in lieu of writing the soft output values to the channel RAM.

Additionally, various modifications are provided, which achieve a wide range of performance and computational overhead trade-offs according to system design considerations.

A simplified summary is provided herein to help enable a basic or general understanding of various aspects of exemplary, non-limiting embodiments that follow in the more detailed description and the accompanying drawings. This summary is not intended, however, as an extensive or exhaustive overview. The sole purpose of this summary is to present some concepts related to the various exemplary non-limiting embodiments of the disclosed subject matter in a simplified form as a prelude to the more detailed description that follows.

### BRIEF DESCRIPTION OF THE DRAWINGS

The low power layered decoding techniques for LDPC decoders and related systems and methods are further described with reference to the accompanying drawings in which:

FIG. 1 illustrates an exemplary parity check matrix of a LDPC code and its Tanner graph representation;

FIG. 2 illustrates an overview of a wireless communication environment suitable for incorporation of embodiments of the disclosed subject matter;

FIG. 3 illustrates an exemplary parity-check matrix H 302 depicts a LDPC code as defined in IEEE 802.11n of rate ⅚ with sub-block size of 81;

FIG. 4 depicts an exemplary non-limiting block diagram of a layered LDPC decoder suitable for incorporation of embodiments of the disclosed subject matter;

FIGS. 5A-5B tabulate power consumption (in milliWatts (mW)) for different parts of a layered decoder for the LDPC code defined in IEEE 802.11n when operated in rate ⅚ mode according to exemplary implementations;

FIG. 6 tabulates exemplary IEEE 802.11n LDPC codes with sub-block size 81 suitable for incorporation of embodiments of the disclosed subject matter;

FIGS. 7A-7D depict a non-limiting example of a bypassing operation for the Channel RAM in an exemplary layered LDPC decoder, in which: FIG. 7A depicts an exemplary pipelined operation of Channel RAM for three layers; FIG. 7B depicts three consecutive exemplary layers of the matrix; FIG. 7A depicts; FIG. 7C depicts Channel RAM operation with natural order; and FIG. 7D depicts exemplary Channel RAM operation with memory bypassing according to various aspects of the disclosed subject matter;

FIG. 8 tabulates the number of the overlapped columns in consecutive layers for the LDPC codes defined in IEEE 802.11n for best case order, natural order, and worst case order;

FIGS. 9A-9B depict a non-limiting example of memory operation for the Channel RAM with different read and write order for the matrix shown in FIGS. 7A and 7B in an exemplary layered LDPC decoder, in which: FIG. 9A depicts exemplary channel RAM operation, FIG. 9B depicts exemplary intermediate data storing memory operation with different read and write order, FIG. 9C depicts exemplary channel RAM 406 operation 900C, FIG. 9D depicts exemplary intermediate data storing memory 416 operation 900D with different read and write order (e.g., a decoupled order or a decoupled read-write order) by considering the overlapping of three consecutive layers for the matrix shown in FIGS. 7A and 7B according to various aspects of the disclosed subject matter;

FIG. 10 depicts an exemplary non-limiting block diagram of a layered LDPC decoder with memory bypassing according to various non-limiting embodiments of the disclosed subject matter;

FIG. 11 tabulates number of the read and write access operations for Channel RAM per iteration of the LDPC codes defined in traditional IEEE 802.11n and after using the memory bypassing per iteration during the decoding according to various non-limiting embodiments of the disclosed subject matter;

FIG. 12 tabulates total number of overlapped columns when considering overlap of the three consecutive layers for LDPC codes defined in IEEE 802.11n;

FIG. 13 is an exemplary block diagram illustrating a complete undirected graph G=(V, E) for a base matrix having four rows suitable for determining optimal order of layers in a layered decoding algorithm according to various non-limiting embodiments of the disclosed subject matter;

FIGS. 14-16 tabulate the total number of overlapped columns considering three-layer overlapping for the LDPC codes, in which FIG. 14 tabulates total number of overlapped columns for the LDPC codes defined in IEEE 802.11n, FIG. 15 tabulates total number of the overlapped columns the LDPC codes defined in IEEE 802.16e, and FIG. 16 tabulates total number of the overlapped columns for the LDPC codes defined in IEEE DVB-S2;

FIG. 17 depicts an exemplary non-limiting block diagram of a layered LDPC decoder with memory bypassing according to further non-limiting embodiments of the disclosed subject matter;

FIG. 18 tabulates an exemplary non-limiting order of the layers and the order of the sub-blocks in the layers for the LDPC decoders of FIG. 17, where “0*” indicates an idle operation;

FIGS. 19-21 tabulate performance of the various exemplary implementations of decoders, in which FIG. 19 tabulates clock cycles required per iteration and idle cycles in percentage, FIG. 20 tabulates power consumption (in mW) of the two LDPC decoders when operated in 250 MHz and 10 iterations, and FIG. 21 tabulates further performance characteristics for different LDPC decoder implementations;

FIG. 22 illustrates an exemplary non-limiting block diagram of an LDPC decoder utilizing memory bypassing and thresholding according to various non-limiting embodiments of the disclosed subject matter;

FIG. 23 depicts the decoding performance of particular non-limiting embodiments (e.g., rate ⅚ LDPC code) in terms of frame error rate (-) and bit error rate (--) of the different decoding algorithms;

FIG. 24 depicts simulation results of normalized memory access (in terms of # of bit read and write) of FIFO for rate ⅚ LDPC code defined in IEEE 802.11n;

FIG. 25 illustrates an exemplary non-limiting decoding apparatus suitable for performing various techniques of the disclosed subject matter;

FIG. 26 illustrates an exemplary non-limiting system suitable for performing various techniques of the disclosed subject matter;

FIG. 27 illustrates a non-limiting block diagram illustrating exemplary high level methodologies according to various aspects of the disclosed subject matter;

FIGS. 28-31 tabulates power consumption (in mW) of three particular non-limiting LDPC decoders, a traditional layered decoding architecture of FIG. 4, a layered decoding architecture with memory bypassing, and a layered decoding architecture combining both memory bypassing and thresholding, in which: FIG. 28 tabulates power consumption when operated in rate ½ mode; FIG. 29 tabulates power consumption when operated in rate ⅔ mode; FIG. 30 tabulates power consumption when operated in rate ¾ mode; and FIG. 31 tabulates power consumption when operated in rate ⅚ mode;

FIG. 32 is a block diagram representing an exemplary non-limiting networked environment in which the disclosed subject matter may be implemented; and

FIG. 33 is a block diagram representing an exemplary non-limiting computing system or operating environment in which the disclosed subject matter may be implemented.

### DETAILED DESCRIPTION

### Overview

Simplified overviews are provided in the present section to help enable a basic or general understanding of various aspects of exemplary, non-limiting embodiments that follow in the more detailed description and the accompanying drawings. This overview section is not intended, however, to be considered extensive or exhaustive. Instead, the sole purpose of the following embodiment overviews is to present some concepts related to some exemplary non-limiting embodiments of the disclosed subject matter in a simplified form as a prelude to the more detailed description of these and various other embodiments of the disclosed subject matter that follow. It is understood that various modifications may be made by one skilled in the relevant art without departing from the scope of the disclosed subject matter. Accordingly, it is the intent to include within the scope of the disclosed subject matter those modifications, substitutions, and variations as may come to those skilled in the art based on the teachings herein.

In consideration of the above-described limitations, in accordance with exemplary non-limiting embodiments, the disclosed subject matter provides low power layered decoding systems and methods for LDPC decoders. Advantageously, exemplary non-limiting embodiments of the disclosed subject matter can achieve significant reduction in memory access of the associated memories depending on the decoding algorithm (e.g., code rate) and the characteristic of the LDPC parity check matrix, thereby providing significant reductions power consumption of LDPC decoders. According to further non-limiting embodiments, the disclosed subject matter can further reduce power consumption by employing the disclosed thresholding scheme.

### DETAILED DESCRIPTION

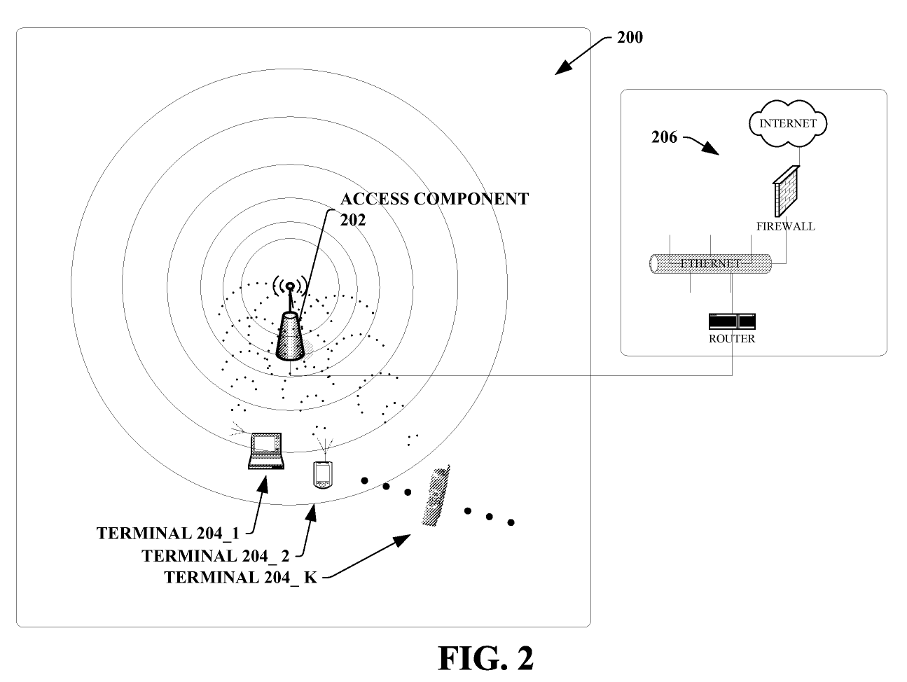

FIG. 2 is an exemplary, non-limiting block diagram generally illustrating a wireless communication environment 200 suitable for incorporation of embodiments of the disclosed subject matter. Wireless communication environment 200 contains a number of terminals 204 operable to communicate with a wireless access component 202 over a wireless communication medium and according to an agreed protocol. As described in further detail below, such terminals and access components typically contain a receiver and transmitter configured to receive and transmit communications signals from and to other terminals or access components.

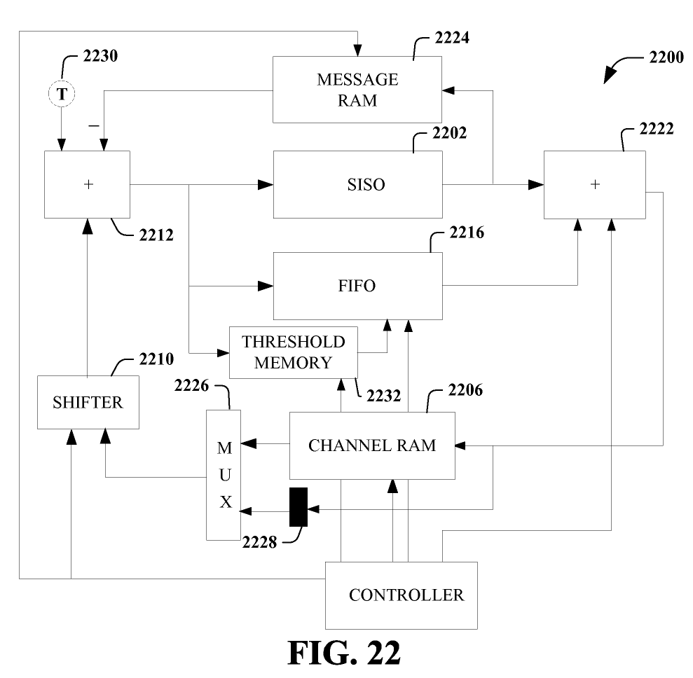

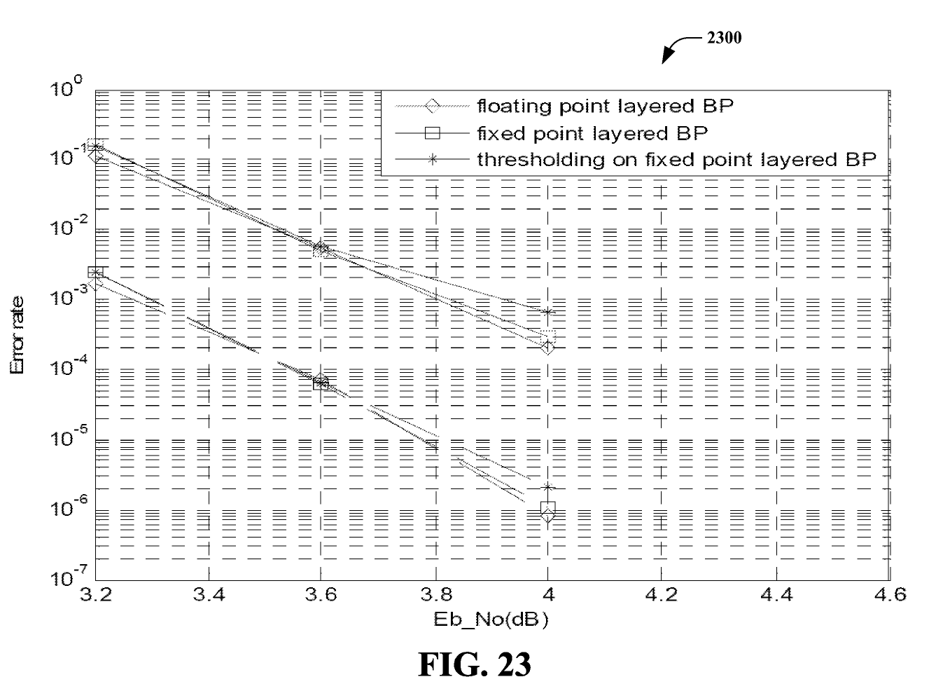

FIG. 2. illustrates that there can be any arbitrary integral number of terminals, and it can be appreciated that due to the mobile nature of such devices and other variables, the subject disclosed subject matter is well-suited for use in such a diverse environment. Optionally, the access component 202 may be accompanied by one or more additional access components and may be connected to other suitable networks and or wireless communication systems as described below with respect to FIGS. 22-23. Additionally, it is contemplated that, for terminals suitably configured to allow such communication, the terminals can communicate wirelessly, between and among terminals in a peer-to-peer fashion.

It can be appreciated that the disclosed subject matter applies to any device wherein it may be desirable to communicate data, e.g., to or from a mobile device. It should be understood, therefore, that handheld, portable and other computing devices and computing objects of all kinds are contemplated for use in connection with the disclosed subject matter, e.g., anywhere that a device may communicate data or otherwise receive, process or store data.

In addition, while an embodiment can be described herein in context of a hardware component performing particular functions, performing particular operations, and/or providing particular functionality, it is not meant to be limiting as those of skill in the art will appreciate that some or all operations, functions, or functionality (or portions thereof) described hereinafter may also be implemented either wholly or partly in software, firmware, and/or special purpose or general purpose hardware. Thus, it should be appreciated that the subject matter disclosed herein, or portions thereof, may have aspects that are wholly in hardware, partly in hardware and partly in software (including firmware), as well as in software.

### Low Density Parity Check (LDPC) Codes

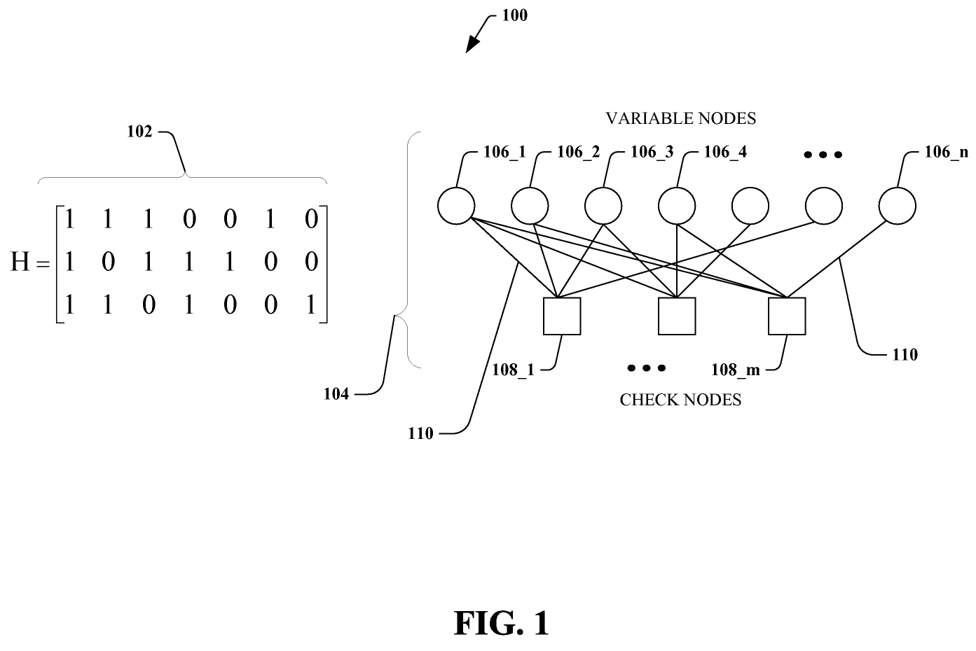

Referring back to FIG. 1, the sparse parity check matrix H 102 can define a linear block code (e.g., a LDPC code), which can also be represented as the Tanner Graph 104) according to aspects of the disclosed subject matter. For example, variable nodes 106 can represent the bits of a codeword, and check nodes 108 can implement parity-check constraints. Typically, a message passing algorithm (also known as “sum-product” or “belief propagation” (BP) Algorithm), can iteratively exchange messages between the check nodes 108 and the variable nodes 106 along the edges 110 of the graph 104.

As described above, the two types of layered decoding schemes can be used to achieve higher convergence speed (e.g., vertical layered decoding and horizontal layered decoding), which LDPC decoder architectures can be further classified into three types (e.g., fully parallel architecture, serial architecture, and partially parallel architecture). Advantageously, partially parallel architecture implementations can use multiple processing units, which allow various design tradeoffs between hardware cost and required throughput. As a result, partially parallel architecture implementations are more commonly adopted in actual implementations.

As further described above, while partially parallel architectures based on layered decoding algorithms can efficiently reduce hardware costs and speed up convergence rate, high power consumption of the LDPC decoder is still a challenging design problem. For example, due to the large amount of data access of the associated memories, it can be shown that power consumption of the memory accounts for most of the power consumption of the decoder. Thus according to various non-limiting embodiments, the disclosed subject matter provides low power LDPC decoder systems and methods that reduce the power consumption of the associated memories.

The aforementioned algorithms can reduce the memory storage required for check node 108 to variable node 106 messages and reduce power consumption of the associated memories of the LDPC decoder with insignificant performance loss. However, it can be shown that power consumption of the associated memories can still account for more than half of the total power consumption of the decoder, due to the large amount of data access in every clock cycle.

Advantageously, various non-limiting embodiments of the disclosed subject matter can provide additional reductions in power consumption of the associated memories. For instance, according to an aspect, the disclosed subject matter can reduce power consumption by reducing the amount of the memory access. For example, various non-limiting embodiments of the disclosed subject matter can reduce the amount of the memory access, thereby providing further power reductions, by utilizing the characteristic of the LDPC parity check matrix and the decoding algorithm.

While various non-limiting embodiments are described herein with reference to the LDPC code specified in the IEEE 802.11n standard, it is to be appreciated that such embodiments are intended to merely serve as an example to illustrate the concepts described herein. Thus, it is to be understood that other similar embodiments may be used or modifications and additions may be made to the described embodiments for performing the same function of the disclosed subject matter without deviating therefrom. Therefore, the disclosed subject matter should not be limited to any single embodiment, but rather should be construed in breadth and scope in accordance with the appended claims.

Accordingly, when the property of the parity check matrices of IEEE 802.11n LDPC code is analyzed, it can be observed that the read and write access of the memory (hereinafter “Channel RAM”) storing the soft output or posterior reliability values of the receive bits can be bypassed to reduce the amount of the memory access. Advantageously, various non-limiting embodiments of the disclosed subject matter can achieve significant reduction in memory access of the Channel RAM through bypassing the Channel RAM depending on the code rate and/or the parity matrix of the LDPC code, which is also referred to as memory-bypassing. According to further non-limiting embodiments, the disclosed subject matter can further reduce power consumption by employing the disclosed thresholding techniques.

For example, embodiments of the disclosed subject matter can determine that when the magnitudes of the intermediate soft values of the variable nodes 106 are larger than or equal to a preset threshold, a one-bit signal can be used to indicate such a situation instead of being read and/or written during the decoding. According to various aspects, a preset threshold value can be used as a magnitude of soft messages in updating of check nodes 108 instead of actual message values. Accordingly, various embodiments of the disclosed subject matter can reduce the amount of memory access to store intermediate soft values.

### LDPC Decoding Algorithms

The following discussion provides additional background information regarding LDPC decoding algorithms to facilitate understanding the techniques described herein. As described above with reference to FIG. 1, LDPC codes are linear block codes that can be characterized by a sparse matrix (H) 102 (e.g., a parity-check matrix). For instance, the set of valid codewords C can be defined as:

H·x^{T}=0 ∀x ε C (1)

The LDPC code can also be described by means of a bipartite graph, known as Tanner graph 104. The Tanner graph 104 comprises two entities, variable nodes (VN) 106 and check nodes (CN) 108, connected to each other through a set of edges 110. An edge 110 links the check node m 108 to the variable node n 106 if the element H_{m,n} of the parity check matrix 102 is non-null. According to various aspects of the disclosed subject matter, optimal LDPC decoding can be achieved by using a message passing algorithm, also known as “belief propagation” (BP), which can be described as an iterative exchange of messages along the edges 110 of the Tanner graph 104. According to further aspects of the disclosed subject matter, the algorithm can proceed iteratively until a maximum number of iterations are elapsed or a stopping rule is met. For instance, intrinsic Log-Likelihood Ratios (LLRs) of received bits (e.g., variable nodes 106), which can also be referred to as a priori information, can be used as inputs of the algorithm.

In the following discussion that describes the belief propagation algorithm, R_{m,n}^{(q)} denotes the check-to-variable message for check node m 108 to variable node n 106 at the q^{th} iteration, Q_{m,n}^{(q)} denotes the variable-to-check message for variable node n 106 to check node m 108 at the q^{th} iteration, Mₙ is the set of the neighboring check nodes 108 of variable node n 106, and Nₘ denotes the set of the neighboring variable nodes 106 of check node m 108. Thus, according to various aspects of the disclosed subject matter, in the q^{th} iteration, the variable node 106 process and the check node 108 process can be computed as follows.

Embodiments of the disclosed subject matter can compute variable node(s) 106, where the variable node n 106 receives the messages R_{m,n}^{(q)} from the neighboring check nodes 108 and propagates back the updated messages Q_{m,n}^{(q)} as:

$${Q}_{m , n}^{( q )} = {λ}_{n} + {\sum }_{i ∈ \{ {M}_{n} \backslash m \}} {R}_{i , n}^{( q )} \qquad ( 2 )$$

where λₙ denotes the intrinsic LLR of the variable node n 106. At the same time, the posterior reliability value, also referred to as soft output for variable node n 106, can be given by:

$${Λ}_{n}^{( q )} = {λ}_{n} + {\sum }_{i ∈ \{ {M}_{n} \}} {R}_{i , n}^{( q )} \qquad ( 3 )$$

Embodiments of the disclosed subject matter can further compute check node(s) 108, where the check node m 108 combines together messages Q_{m,m}^{(q)} from the neighboring variable nodes 106 to compute the updated messages R_{m,n}^{(q+1)}, which can be sent back to the respective variable node. Accordingly, update can be performed separately on signs and magnitudes as:

$$\begin{matrix}- sgn ( {R}_{m , n}^{( q + 1 )} ) = {\prod }_{j ∈ \{ {N}_{m} \backslash n \}} - sgn ( {Q}_{m , j}^{( q )} ) & ( 4 ) \\ \vert {R}_{m , n}^{( q + 1 )} \vert = {Φ}^{- 1} \{ {\sum }_{j ∈ \{ {N}_{m} \backslash n \}} Φ ( \vert {Q}_{m , j}^{( q )} \vert ) \} \\ where & ( 5 ) \\ Φ ( x ) = {Φ}^{- 1} ( x ) = - log ( tanh ( \frac{x}{2} ) ) & ( 6 )\end{matrix}$$

According to various non-limiting embodiments of the disclosed subject matter, layered decoding scheduling can be employed by viewing the parity check as a sequence of check through horizontal or vertical layers to advantageously improve the convergence speed and reduce the number of iterations. According to an aspect of the disclosed subject matter, the intermediate updated messages can be used in the updating of the next layer. To that end, the layered decoding principle for horizontal layers can be expressed by:

$$\begin{matrix}- sgn ( {R}_{m , n}^{( q + 1 )} ) = {\prod }_{j ∈ \{ {N}_{m} \backslash n \}} - sgn ( {Γ}_{m , j}^{( q + 1 )} ) & ( 7 ) \\ \vert {R}_{m , n}^{( q + 1 )} \vert = {Φ}^{- 1} \{ {\sum }_{j ∈ \{ {N}_{m} \backslash n \}} Φ ( \vert {Γ}_{m , j}^{( q + 1 )} \vert ) \} \\ and & ( 8 ) \\ {Γ}_{m , n}^{( q + 1 )} = {Λ}_{n}^{( q + 1 )} [ k - 1 ] - {R}_{m , n}^{( q )} & ( 9 ) \\ {Λ}_{n}^{( q + 1 )} [ k ] = {Γ}_{m , n}^{( q + 1 )} + {R}_{m , n}^{( q + 1 )} & ( 10 )\end{matrix}$$

where k denotes the time step that the CN is updated within an iteration. It can be appreciated that Eqns. (7)-(10) can be derived by merging the variable node process and the soft-output updating process (e.g., Eqns. (2)-(3)) with the CN update process (e.g., Eqns. (4)-(5)). According to a further aspect, the variable node process can be spread on the check node updating and the posterior reliability value, Λₙ^{q+1)}, can be refreshed after every check node update. According to further non-limiting embodiments, the disclosed subject matter can increase the convergence speed and reduce the average number of iteration time by up to 50%, by employing layered decoding scheduling to facilitate the intermediate update of posterior messages to accomplish the propagation to the next layers within the iteration.

While the computation of Eqns. (6) and (8) can be complicated and cumbersome to implement in hardware, low complexity algorithms such as min-sum approximation can be employed to reduce the computation complexity, according to further aspects of the disclosed subject matter. For example, according to the min-sum decoding algorithm, the computation of Eqn. (8) can be approximated and expressed by:

$$\vert {R}_{m , n}^{( q + 1 )} \vert = {min}_{j ∈ \{ {N}_{m} \backslash n \}} \vert {Γ}_{m , j}^{( q + 1 )} \vert \qquad ( 11 )$$

Thus, for a check node m 108, only two of the incoming messages with the smallest magnitudes have to be determined to compute the magnitudes of the outgoing messages, according to various non-limiting embodiments of the disclosed subject matter. As a result, the disclosed subject matter can advantageously reduce the computation complexity of Eqn. (8) significantly. In addition, the storage of the outgoing messages has been advantageously reduced to two as opposed to dc, where dc denotes the check node degree (e.g. number of the neighboring variable nodes 106 of a check node 108), because dc-1 variable nodes 106 share the same outgoing message. According to further non-limiting embodiments of the disclosed subject matter, variants of the min-sum algorithm (e.g., offset min-sum, two-output approximation, etc.) are contemplated and can be adopted into implementations of the disclosed subject matter. Advantageously, such implementations can achieve better performance and maintain similar computation complexity and storage requirement of the min-sum approximation described above.

### Layered Decoder Architectures

As described above, layered decoding algorithms have been adopted in decoding designs due to the associated high convergence speed and easy adaptation to the flexible LDPC codes. For example, a decoder architecture with layered decoding algorithm for architecture-aware LDPC codes (AA-LDPC) is described. Architecture-aware codes are structured codes, whose parity-check matrix is built according to specific patterns, and as such, they can be used to facilitate hardware design of decoders. Advantageously, architecture-aware codes are suitable for VLSI design, because the interconnection of the decoder is regular and simple, and trade-offs between throughput and hardware complexity are relatively straightforward. In addition, because architecture-aware codes support efficient partial-parallel hardware VLSI implementations, AA-LDPC codes have been adopted in several modern communication standards, such as DVB-S2, IEEE 802.16e and IEEE 802.11n.

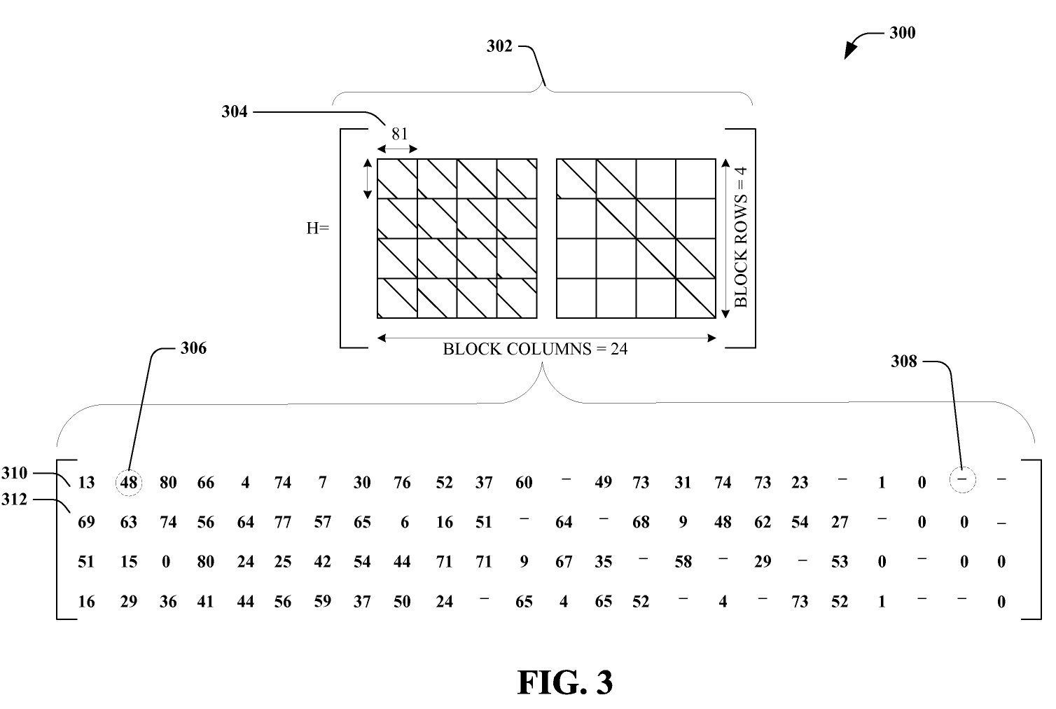

FIG. 3 illustrates an exemplary parity-check matrix H 302 that depicts a LDPC code as defined in IEEE 802.11n of rate ⅚ with sub-block size (e.g. the size of the identity sub-matrix) of 81 (304). The parity-check matrix H 302 comprises a null sub-matrix or identity sub-matrix with different cyclic shifts. For example, the numbers (e.g., 306) stand for the cyclic shift value of the identity sub-matrix, and the “−” (308) stands for null sub-matrix.

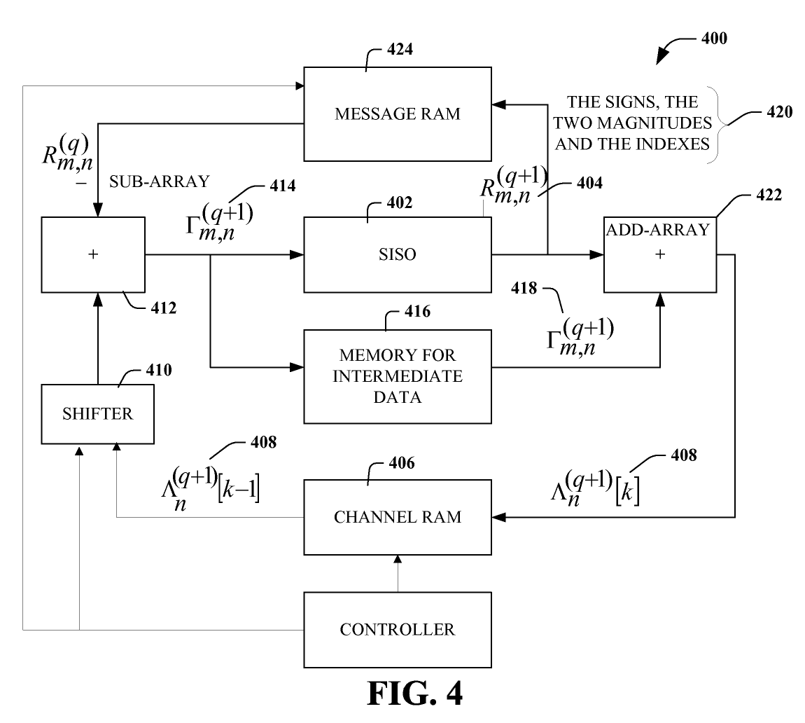

FIG. 4 depicts an exemplary non-limiting block diagram of layered LDPC decoder 400 suitable for incorporation of embodiments of the disclosed subject matter. For instance, several VLSI architectures can be used for the decoder 400 and layered decoding algorithm adopted in the design of such systems. For example, in the decoder 400, multiple soft-in soft-out (SISO) units 402 (shown as one block in FIG. 4 for simplicity) can be used to work in parallel to calculate multiple check node processes 404 for a layer, according to various aspects of the disclosed subject matter. According to further aspects, Channel RAM 406 can be used to store the input LLR value of the received data initially. During the iteration of the decoding, Channel RAM 406 can be used to store the posterior reliability values 408 (also referred to as soft output) of the variable nodes 106. According to still further aspects of the disclosed subject matter, shifter 410 can be used to perform the cyclic shift of the soft output messages 408 (also referred to as posterior reliability value) so that the correct message is read out from the Channel RAM 404 and sent to the corresponding SISO 402 for calculation based on the base matrix. According to further aspects, Sub-array 412 can be used to perform the subtraction of Eqn. (9), and the results 414 can be sent to the SISO unit 402 and the memory 416 (also referred to as FIFO or memory for storing intermediate data) used to store these intermediate results 418 at the same time.

Accordingly, the SISO unit 402 can perform the check node process of equations (7) and (8). According to various aspects of the disclosed subject matter, the two-output approximation can be used for the SISO computation (402), and two outgoing magnitudes 420 are generated for a check node 108. One is for the least reliable incoming variable node 106, and the other is for the rest of the variable nodes 106. Thus, the SISO unit 402, for every check node 108, can generate the signs 420 for the outgoing messages of all the variable nodes 106, two magnitudes 420 and an index 420. According to an aspect of the disclosed subject matter, the index 420 can be used to select the two magnitudes 420 for the update process in the Add-array 422. According to further aspects, the data generated by the SISO 402 can be stored in the Message RAM 424. Thus, the Add-array 422 can perform the addition of Eqn. (10), by taking the output of the SISO 402 and intermediate results 418 stored in the memory 416. The results of the Add-array 422 can be written back to the Channel RAM 406. According to various non-limiting embodiments of the disclosed subject matter, pipeline operation of the decoder can be implemented in the decoder to increase the decoder throughput.

The basic architecture shown in FIG. 4 for the IEEE 802.11n standard using a 0.18 micron (μm) Complementary Metal-Oxide-Semiconductor (CMOS) technology is implemented as a baseline for performance comparison. In addition, the partial-parallel architecture uses 81 SISO.

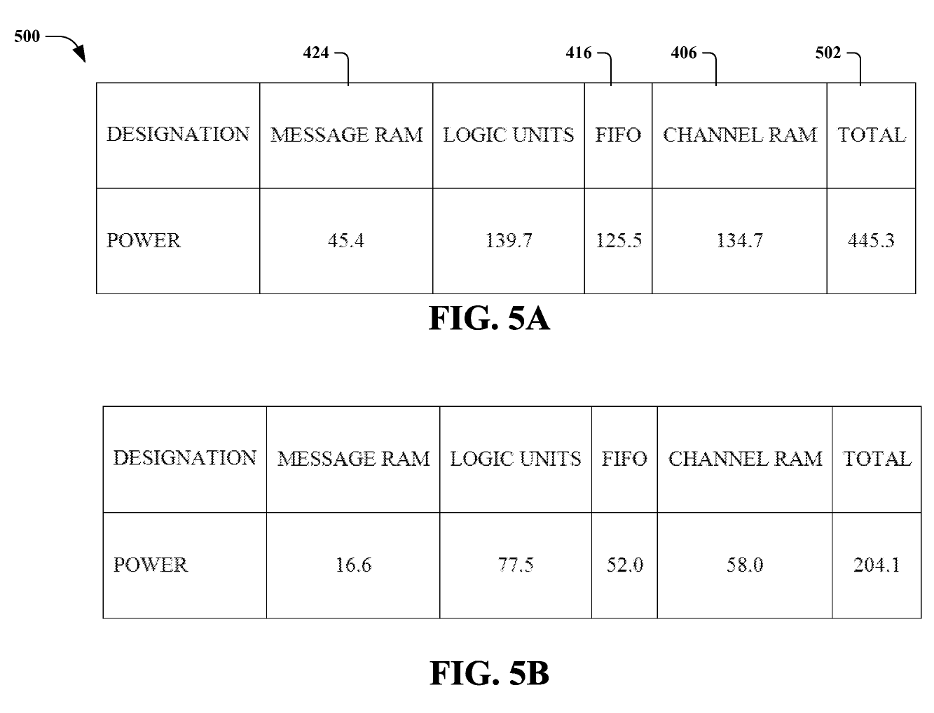

FIG. 5 tabulates power consumption (in mW) for different parts of a layered decoder for the LDPC code defined in IEEE 802.11n when operated in rate ⅚ mode. From FIG. 5, it can be seen that the power consumption of the memories, including the Channel RAM 406, the memory 416 storing the intermediate data (e.g. FIFO in FIG. 5), and the Message RAM 424, contributes most to the total power consumption 502 of the LDPC decoder. In particular, the Channel RAM 406 and the FIFO 416 consume nearly half of the power consumption of the decoder, due to the frequent read and write access. Accordingly, various non-limiting embodiments can reduce the power consumption of the Channel RAM 406 and the FIFO 416 according to various aspects of the disclosed low power LDPC decoder.

### Low Power Layered Decoding for Low Density Parity Check Using Memory Bypassing

As described above, while various non-limiting embodiments are described herein with reference to the LDPC code specified in the IEEE 802.11n standard, it is to be appreciated that such embodiments are intended to merely serve as an example to illustrate the concepts described herein. Accordingly, the IEEE 802.11n standard defines three different sub-block sizes for the identity matrix, which are 27, 54 and 81, and four types of code rate ½, ⅔, ¾ and ⅚. All the base matrices have the same number of the block columns N_{b}=24. In the following illustrated embodiments, LDPC codes with sub-block size 81 and code rate of ½, ⅔, ¾ and ⅚ are described as an example to demonstrate the implementation of the disclosed subject matter.

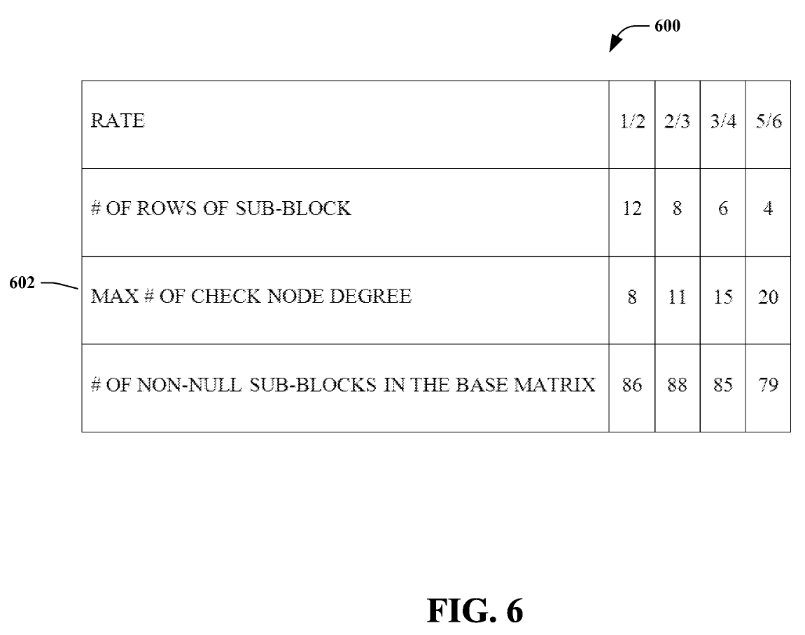

FIG. 6 tabulates exemplary IEEE 802.11n LDPC codes with sub-block size 81 suitable for incorporation of embodiments of the disclosed subject matter, where check node degree 602 refers to the number of the neighboring variable nodes 106 of a check node 108. It can be appreciated that during decoding, for every layer, the soft messages 408 are read from and wrote into the Channel RAM 406 and the FIFO 416 every cycle. Accordingly, various non-limiting embodiments of the disclosed subject matter can reduce the power consumption of the memories (e.g., 406 and 416) by minimizing the amount of data access of the memories (e.g., 406 and 416).

As described above, the Channel RAM 406 stores the soft posterior reliability values 408 of the variable nodes 106, which are stored back from the Adder-array 422 and will be used in the update of the subsequent layer. According to various non-limiting embodiments of the disclosed subject matter, if both of the layers have non-null matrix at the same column, the results of the Add-array 422 can be directly sent to the cyclic shifter 410 and used directly for the decoding of the next layer. As a result, the disclosed subject matter can advantageously bypass the write operation for the current layer and the read operation for the next layer.

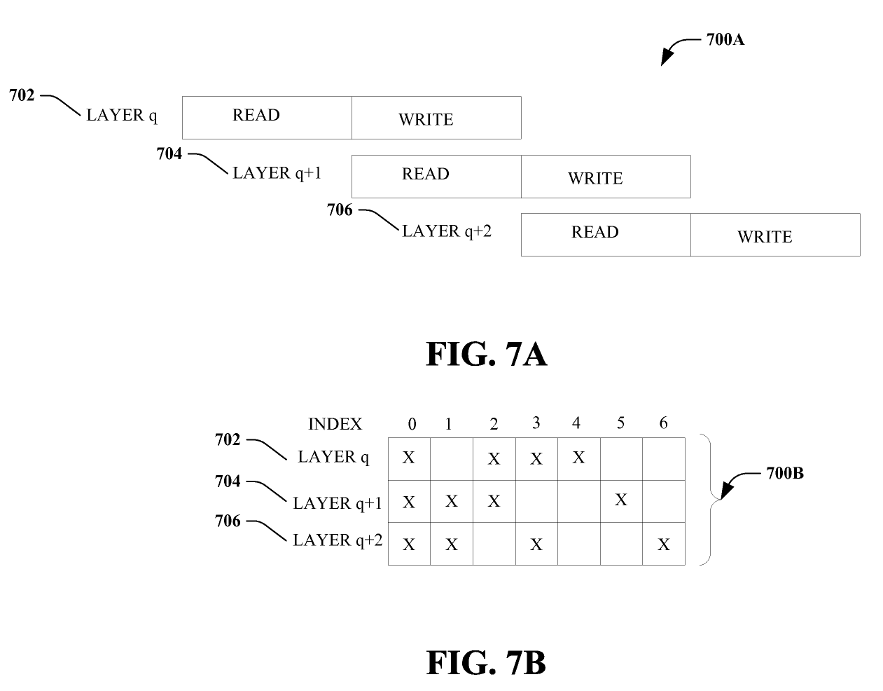

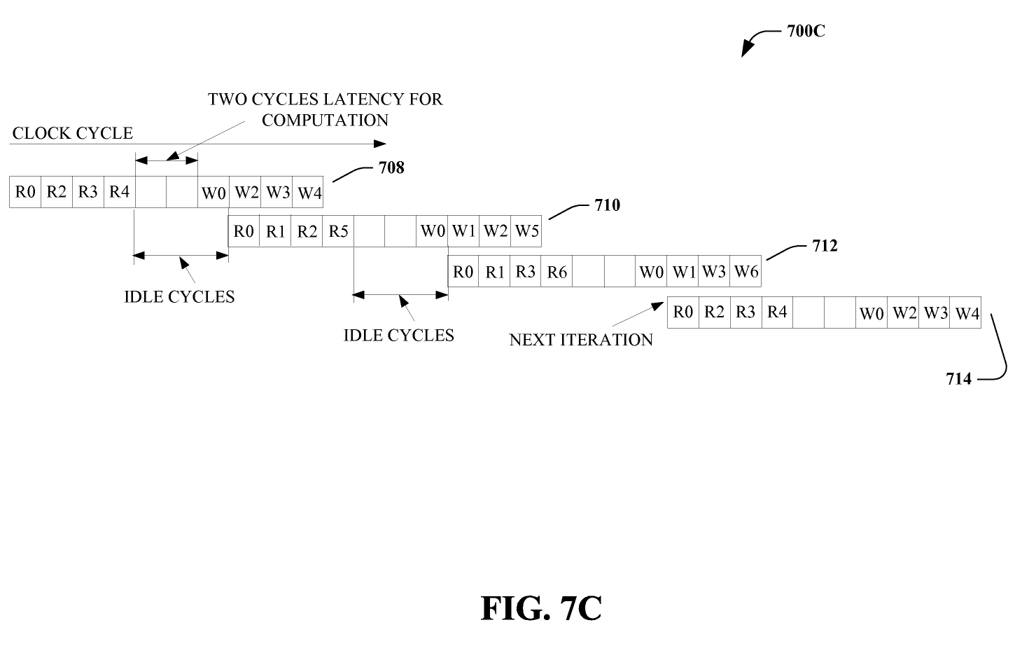

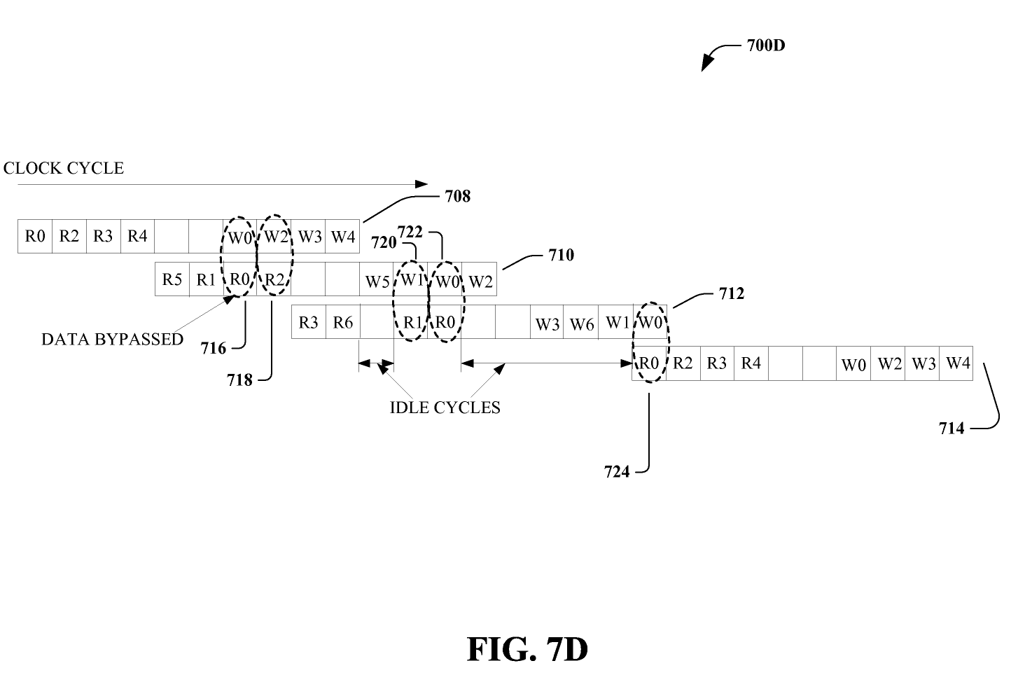

FIGS. 7A-7D depict a non-limiting example of a bypassing operation for the Channel RAM 406 in an exemplary layered LDPC decoder 400. For example, FIG. 7A depicts an exemplary pipelined operation illustrating the timing diagram of the pipeline of the Channel RAM 406 for three layers (702, 704, 706). FIG. 7B depicts three consecutive exemplary layers (702, 704, 706) of the matrix 700B. FIG. 7C depicts Channel RAM 416 operation 700C with natural order. Without any memory bypassing (FIGS. 7A-7B), the number of read and write access operations for the Channel RAM 406 is equal to the non-null entries in the matrix 708, which in this example is 12.

FIG. 7D depicts exemplary Channel RAM 416 operation with memory bypassing according to various aspects of the disclosed subject matter. For instance, if memory bypassing is employed (e.g. instead of writing back the channel RAM 406, the updated soft output values 408 are used directly for the decoding of the next layer), then as described above, the number of memory access operations can be reduced. For example, memory access for columns 0 and 2 (716 and 718) can be bypassed (denoted as data bypassed in FIG. 7D for columns 0 and 2 (716 and 718)) when the decoding proceeds from layer 0 to layer 1 (from layer 708 to layer 710). In addition, memory access for columns 0 and 1 (720 and 722) can be bypassed for the second layer decoding (712), and memory access for column 0 (724) and column 3 (not shown) can be bypassed for the third layer decoding 714. As a result of the memory bypassing according to the disclosed subject matter, 6 out of 12 read and write operation can be bypassed, resulting in a reduction of 50% of the power consumption of the Channel RAM 406.

It should be appreciated that the number of bypasses that can be achieved depends on the structure of the parity-check matrix of the LDPC code. For example, in the IEEE 802.11n codes, there are many overlapped columns in the parity-check matrix. As used herein, the phrases “overlapped column” and “overlapping columns” refers to the occurrence of two consecutive layers that have non-null matrix 308 at the same column or the determination that two consecutive layers have non-null matrix 308 at the same column. For example, in the LDPC code depicted in FIG. 3, the first layer 310 overlaps with the second layer 312 at 17 columns.

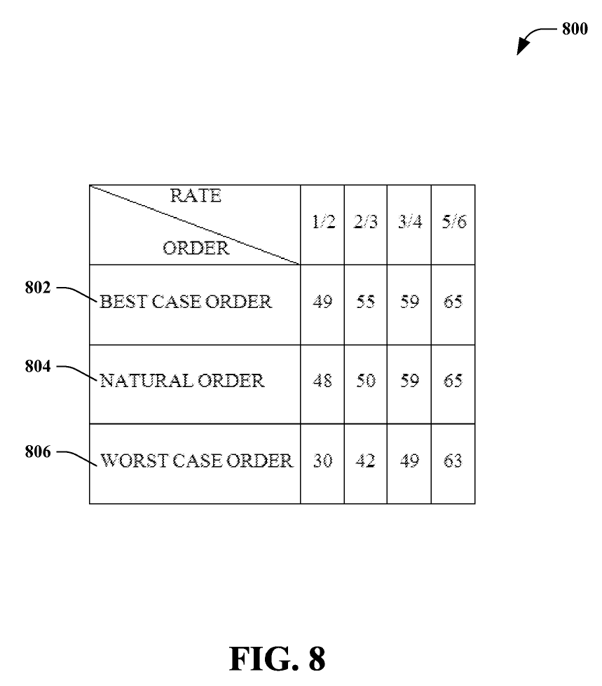

FIG. 8 tabulates the number of the overlapped columns 800 in consecutive layers for the LDPC codes defined in IEEE 802.11n for best case order 802, natural order 804, and worst case order 806. As can be appreciated, the number of the overlapped columns can be affected by the decoding order of the layers. It can be seen from FIG. 8 that the amount of bypass can be achieved varies with different decoding order. Thus, for some codes, finding the optimal order can be more important for memory access reduction and resultant power reduction for some cases of decoding order that for other cases.

According to the particular embodiments of the four codes (e.g., code rate ½, ⅔, ¾ and ⅚) depicted in FIG. 8, there are only 86, 88, 85 and 79 non-null matrices in the base matrices. Accordingly, if all the overlapped columns can be bypassed in the decoder 400 according to the disclosed subject matter, reduction of 57%˜82% of the power consumption of the Channel RAM 406 during the decoding process can be realized. However, it is to be appreciated that to achieve the maximum number of the bypassing operations, the traditional architecture cannot be directly adopted.

For example, assuming it takes two clock cycles for the cyclic shifter 410, Sub-array 412, the SISO 402, and the Add-array 422 to finish the computation after the last incoming variable node 106 is read in, the detail timing diagram showing the operation of the decoder 400 is depicted in FIG. 7C. In addition, the order of read and write of the Channel RAM 406 is following the natural order stated in the base matrix. It should be appreciated that due to data dependency, the memory write of a certain column for the existing layer should finish before or at the same time with the reading of the same column for the subsequent layer. In order to achieve that, the decoding of the second layer is delayed to align the memory access such as by inserting idling cycles in the decoding pipeline. However, idle cycles will decrease the throughput and increase the latency of the decoding. Thus, an optimal decoding order of the layers and the order of the sub-blocks updated within a layer can be determined to reduce the additional idling cycles.

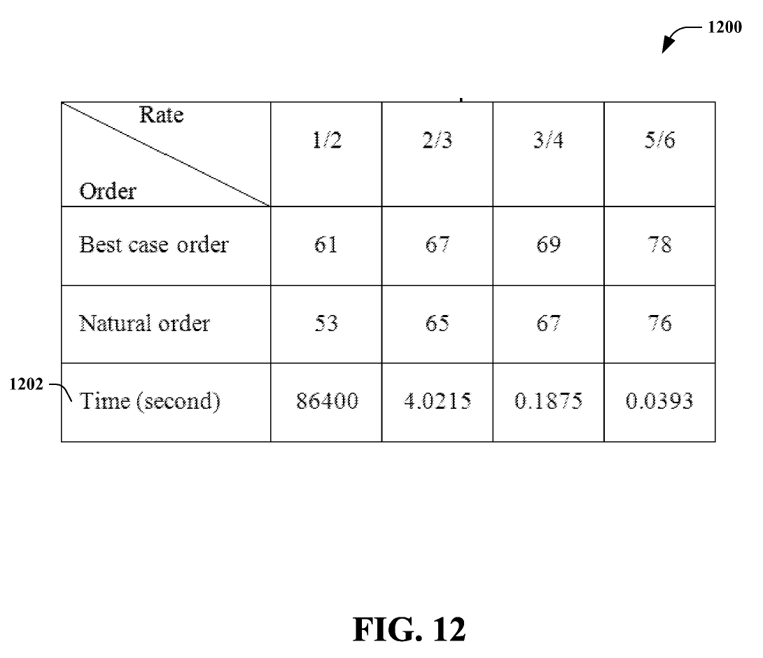

According to various non-limiting embodiments of the disclosed subject matter, memory write operations for the existing layer should occur at the same time with the reading operation of the same column for the subsequent layer o implement memory by-pass for the overlapped columns. As described above, FIG. 7D illustrates such a decoding order, where column 0 and 2 (716 and 718) are written earlier for layer 0 (708) and columns 0 and 2 (716 718) are scheduled later for layer 1 (710) so that the overlap can be achieved. However, while adding idling delay can maximize the overlap with respect to layer 0 (708) and layer 1, even with that there is still one potential overlap (W3, R3) in the third layer 714 that cannot be achieved. Thus, according to further non-limiting embodiments of the disclosed subject matter, the read and write order of the memory storing the intermediate messages for a layer can be decoupled to achieve the maximum number of bypassing while advantageously reducing the idle cycling at the same time, as further described below regarding FIGS. 12-18, for example.

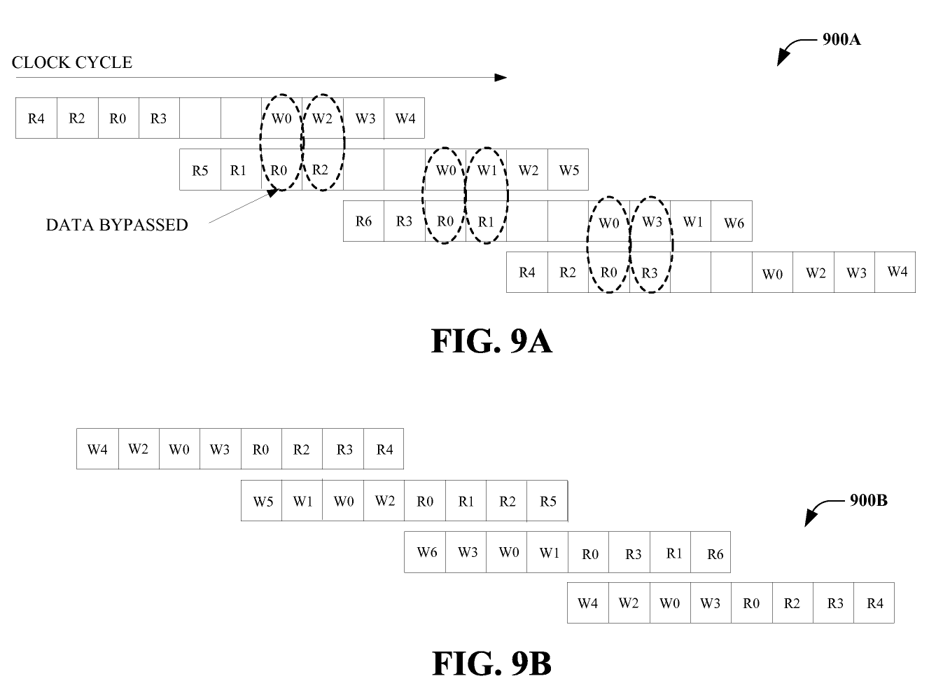

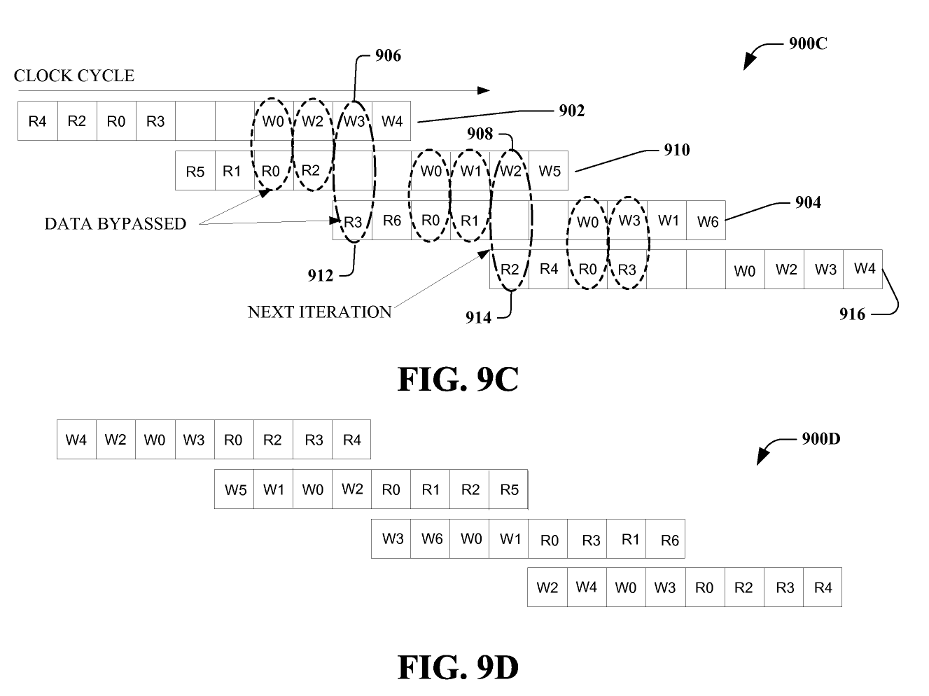

FIGS. 9A-9B depict various non-limiting examples of a memory operation with different read and write order for the matrix shown in FIGS. 7A and 7B in an exemplary layered LDPC decoder 400, in which: FIG. 9A depicts exemplary channel RAM 406 operation 900A, FIG. 9B depicts exemplary intermediate data storing memory 416 operation 900B with different read and write order (e.g., a decoupled order or a decoupled read-write order), FIG. 9C depicts exemplary channel RAM 406 operation 900C, FIG. 9D depicts exemplary intermediate data storing memory 416 operation 900D with different read and write order (e.g., a decoupled order or a decoupled read-write order) by considering the overlapping of three consecutive layers for the matrix shown in FIGS. 7A and 7B according to various aspects of the disclosed subject matter.

For example, according to various non-limiting embodiments of the disclosed subject matter, the above-described exemplary memory bypassing implementation can be described by considering that two consecutive layers having non-null matrix at the same column can be candidates for memory bypassing, for example where it takes two clock cycles for the cyclic shifter 410, Sub-array 412, the SISO 402, and the Add-array 422 to finish the computation after the last incoming variable node 106 is read in (e.g., latency cycles equal to two), and assuming that the number of layers of the matrix (e.g., 700A and 700B of FIGS. 7A and 7B) is three. Accordingly, the following discussion is intended to illustrate this exemplary case, in which the best order of the layers that can minimize memory access rate is described.

Accordingly, it should be understood that the overlapping of more layers can facilitate further reducing the memory access rate, which in turn advantageously reduces power consumption. For example, in FIG. 7B, the first layer 702 and the third layer 706 have non-null matrix 308 at column three (indicated by ‘X’ in the column three (3) for the first layer 702 and the third layer 706), and this overlapping can be used for memory bypassing as described herein. The memory operations considering the overlapping of the three consecutive layers are shown in FIGS. 9C and 9D.

Referring again to FIGS. 9C and 9D, for this exemplary code (e.g., matrix 700B), by considering the overlapping of the first layer 902 and the third layer 904, it can be appreciated that two more memory access operations can be bypassed (e.g., the write operation W3 (906) in first layer 902 and W2 (908) in the second layer 910 can be bypassed with the read operation R3 (912) in the third layer 904 and R2 (914) in the first layer 916 of the next decoding iteration. Considering the overlapping of the three consecutive layers (e.g., 702/902, 704/910, and 706/904), the maximal amount of the memory-bypassing that can be achieved in the current (e.g., layer q+2 (706/904)) is determined by the number of the non-null matrix 308 that the current layer (e.g., layer q+2 (706/904)) have in common with the above two layers (e.g., layer q+1 (704/910) and q (702/902)).

Thus, according to various non-limiting embodiments, the disclosed subject matter can facilitate memory-bypassing by considering the overlapping of layer q+2 (706/904) and layer q (702/902), in which the amount of memory-bypassing is based on the number of the non-null matrix 308 that the current layer q+2 (706/904) has in common with the layers q (706/902) but not in common with layer q+1 (704/910) and the number of the latency cycles (e.g., number of clock cycles for the cyclic shifter 410, Sub-array 412, the SISO 402, and the Add-array 422 to finish the computation after the last incoming variable node 106 is read in). For example, if the number of the non-null matrix 308 that the current layer q+2 (706/904) has in common with the layer q (702/902) but not in common with the layer q+1 (704/910) is smaller than the latency cycles, then it can be appreciated that the amount of the memory-bypassing available will depend only on the LDPC base matrix (e.g., parity check matrix H 102). Otherwise the amount of the memory-bypassing available is limited by the latency cycles.

Accordingly, in various non-limiting embodiments, the disclosed subject matter can utilize additional pipelined stages in the computation elements, for example, in the case where the available memory-bypassing is limited by the latency cycles, in order to achieve the maximum number of memory-bypassing operations. As a further example, in some implementations of the disclosed LDPC decoder architectures and pipeline operations, it can be shown that the overlapping of four or more layers in the base matrix is exceedingly impractical and/or complex.

FIGS. 9A and 9B demonstrate that according to various non-limiting embodiments of the disclosed subject matter, all potential memory bypass operations (denoted as data bypassed in FIG. 9A for columns 0 and 2) can be achieved without adding idling cycles.

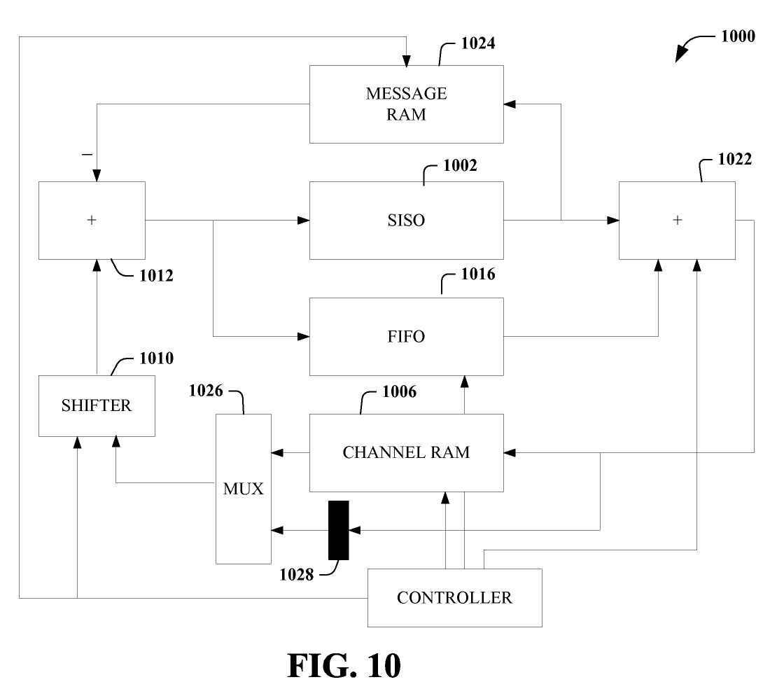

FIG. 10 depicts an exemplary non-limiting block diagram of a layered LDPC decoder 1000 with memory bypassing according to various non-limiting embodiments of the disclosed subject matter. It should be appreciated that the similarly named components of FIG. 10 can have similarly described functionality as described above regarding FIG. 4, except as noted below. In addition, it should be appreciated that the presently described aspects of the disclosed subject matter are suitably incorporated into the previously described decoders. As described above, the memory which can be used to store the intermediate data is referred to as FIFO 1016. According various embodiments of the disclosed subject matter, a bank of multiplexers (muxs) 1026 can be added to select the output of the Add-array 1022 and that of the Channel RAM 1006 and pipeline registers 1028 are added after the Add-array 1022 to facilitate bypassing memory read and write operations.

It should be appreciated that because the order of the messages entering the SISO 1002 (e.g., same as the read order of the Channel RAM 1006) and the order of the messages updated in the Add-array 1022 (e.g., same as the read order of the memory 1016 storing the intermediate data (e.g., RAM1 (416))) are different (e.g., decoupled), the index generated in the SISO 1002 indicating the position of the least reliable incoming messages will be incorrect for the update process. Thus, according to further aspects of the disclosed subject matter, a ROM (not shown) containing the decoupled order of the updated process (e.g. the read order of FIFO 1016) can be added and can be used together with the index generated in the SISO 1002 to select the two magnitudes for the update process. It should be further appreciated that the associated overhead in area and the power is very small by comparison and relatively straightforward to implement.

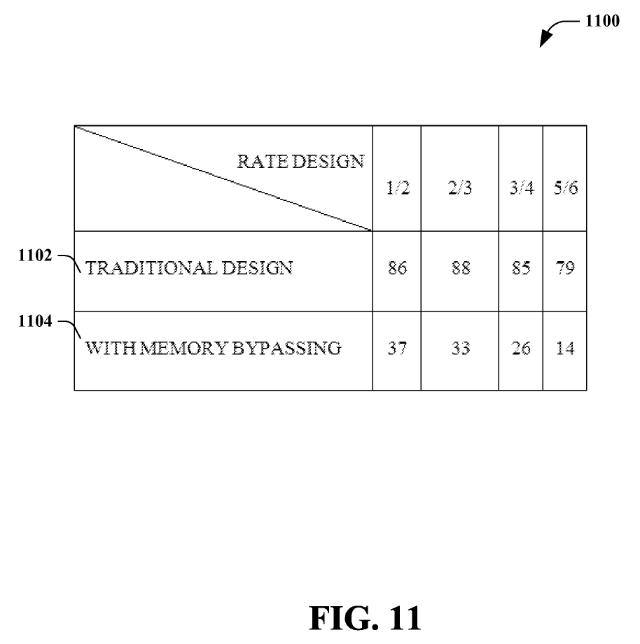

FIG. 11 tabulates number of the read and write access operations 1100 for Channel RAM 1006 per iteration of the LDPC codes defined in traditional IEEE 802.11n 1102 and after using the memory bypassing 1104 per iteration during the decoding according to various non-limiting embodiments of the disclosed subject matter. It can be seen from FIG. 11 that depending on the code rate, 57%˜82% of the memory access of the Channel RAM during the decoding process can be achieved, while the idle cycles are minimized at the same time (e.g., only a few idle cycles are present due to irregular check node degrees). While the power consumption of the Channel RAM 1006 can be reduced, FIFO 1016 which stores the intermediate data still consumes significant power. Thus, according to further non-limiting embodiments, the disclosed subject matter can employ thresholding to further reduce the power consumption of the FIFO 1016 as further described below regarding FIGS. 22-25.

FIG. 12 tabulates total number of overlapped columns when considering the overlapping of the three consecutive layers for LDPC codes defined in IEEE 802.11n. For example, assuming that all the overlapped columns when considering the overlapping over the three consecutive layers utilized for the memory-bypassing operation, a comprehensive algorithm can be constructed to list all combinations of the layers and then compute the number of overlapping (e.g., non-null matrix 308 in common) for every combination for the example codes in IEEE 802.11n code. The results shown in FIG. 12 also tabulate the time required (1202) for the comprehensive algorithm to determine find the best order of the layers as described above regarding FIGS. 7A-7D and FIG. 8, for example.

It can be seen from FIG. 12 that when considering the overlapping of the three consecutive layers, the total number of the overlapped columns (e.g., non-null matrix 308 in common) achieved by the best order is advantageously always larger than that of the natural order. In addition, it can be seen that for the small codes (e.g., rate ⅚) with small number of the layers, the comprehensive algorithm listing all combinations of the layers works quite well. However, it is further apparent that when the base matrix becomes larger (e.g., rate ½), the time required for the comprehensive algorithm to find the best order of the layers increases dramatically. As an example, the LDPC codes defined in DVB-S2 can have 180 layers. Accordingly, for a base matrix with a large number of layers, it can become impractical to utilize a comprehensive algorithm to find the best order of the layers, in which case, the natural order can be substituted as the order in which memory bypass can be implemented according to the disclosed subject matter. In further non-limiting embodiments of the disclosed subject matter, a quick search algorithm that can search for the best order of the layers for LDPC with large base matrix can be utilized.

### Quick Searching Algorithm for Determining the Order of the Layers

As described above, the problem finding the best order of the layers (e.g., that order which produces the maximum amount of overlapping) becomes more relevant as the number of layers in a layered decoding algorithm increases. According to further non-limiting embodiments, a quick searching algorithm is provided which is shown to provide positive results for the exemplary LDPC codes discussed below. In order to simplify the description of the problem and the disclosed implementations, the algorithm to find the best order of the layers having the maximum amount of overlapping of two consecutive layers (two-layer overlapping) is considered first. Thus, it is to be appreciated that the described embodiments are intended to merely serve as an example to illustrate the concepts described herein. Thus, it is to be understood that other similar embodiments may be used and/or modifications (e.g., any number of layers) may be made to the described embodiments according to the concepts disclosed herein without deviating therefrom. Therefore, the disclosed subject matter should not be limited to any single described embodiment, but rather should be construed in breadth and scope in accordance with the appended claims.

Accordingly, a direct method (e.g., the comprehensive algorithm) can list all combinations of layers and compute the amount of overlapping for all the combinations, selecting the best order by maximizing the overlap. For example, if a base matrix of an LDPC code has n rows, it should be appreciated that there are n! (“n factorial”) combinations. As a result, the computation complexity quickly becomes impractical as the number n increases.

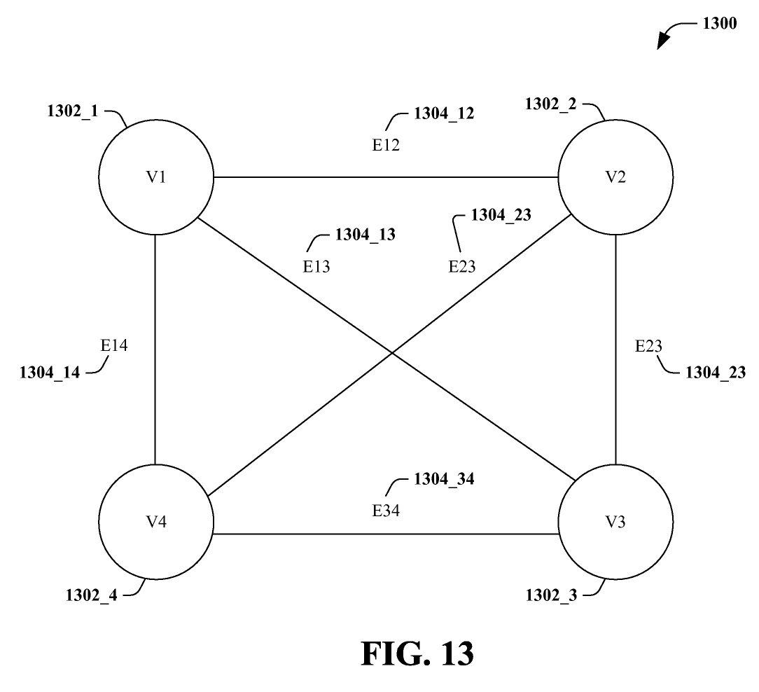

FIG. 13 is an exemplary block diagram illustrating a complete undirected graph 1200 G=(V, E) for a base matrix having four rows suitable for determining optimal order of layers in a layered decoding algorithm according to various non-limiting embodiments of the disclosed subject matter. To address the issue of increasing computation complexity as the number of rows increases (and the resulting computation complexity of the searching algorithm), the problem of finding the optimal order can be modeled into a complete undirected graph G=(V, E). Accordingly, in FIG. 13, V (1302) represents each row in the base matrix and the edge E (1304) as a cost function which can represent the number of overlapping (e.g., non-null matrix 308 in common) between the two rows.

It can be understood that the problem of finding the optimal orders of the layers for two-layer overlapping (e.g., non-null matrix 308 in common) is the same as finding the path starting from any of the node in the undirected graph, visiting all the other nodes exactly once and returning back to the starting node that has the maximal summation of costs of the edges. Thus, the problem of find the path with maximum cost can be determined according to the NP-hard problem known as the traveling salesman problem (TSP). Thus according to further non-limiting embodiments, the computation complexity for determining layer order can be advantageously reduced from n! (“n factorial”) to ½*(n−1)! for n>2 where n is the number of Hamiltonian cycles in a complete graph.

As can be appreciated, the problem of finding the optimal order of the layers having the maximum amount of overlapping (e.g., non-null matrix 308 in common) when considering the overlapping over three consecutive layers (e.g., three-layer overlapping) is almost the same as the problem of finding the optimal orders of the layers for two-layer overlapping. Accordingly, the computation complexity is of same order because the total number of Hamiltonian cycles that are to be compared is the same as two-layer overlapping, except the calculation is more complicated because the path is two nodes away rather than just a path E 1304 to neighboring node (e.g., neighboring V 1302). As a result of the relatively higher computation complexity, a suboptimal algorithm can be applied to find a suboptimal solution in order to reduce the time to find the optimal solution for a large value n. Thus according to further non-limiting embodiments of the disclosed subject matter, a simulated annealing can be applied to determine the orders of the layers having large amount of overlapping for three-layer overlapping.

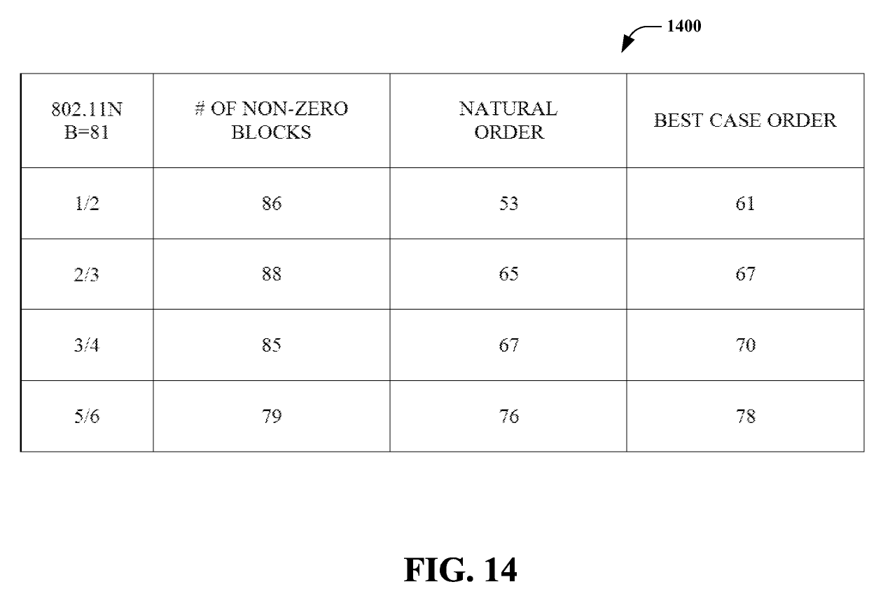

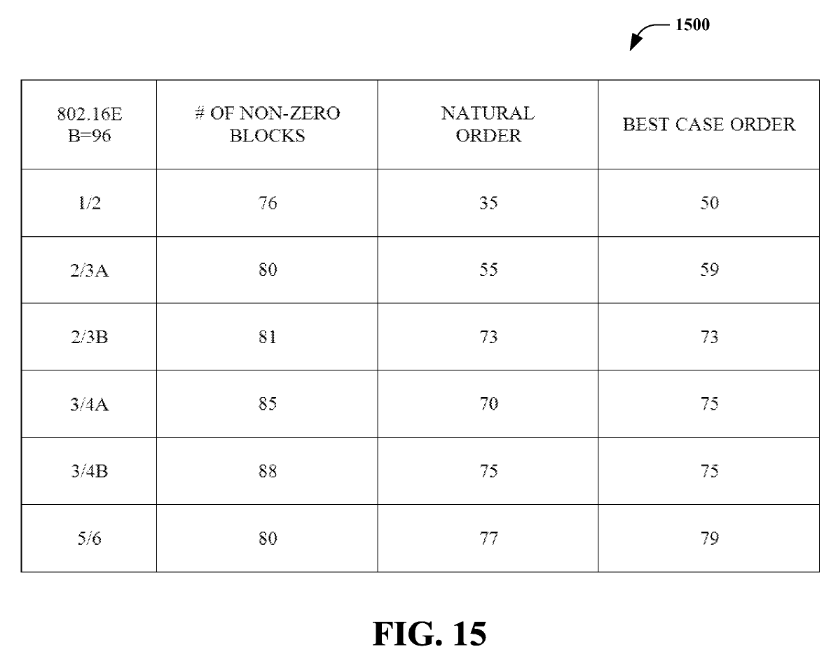

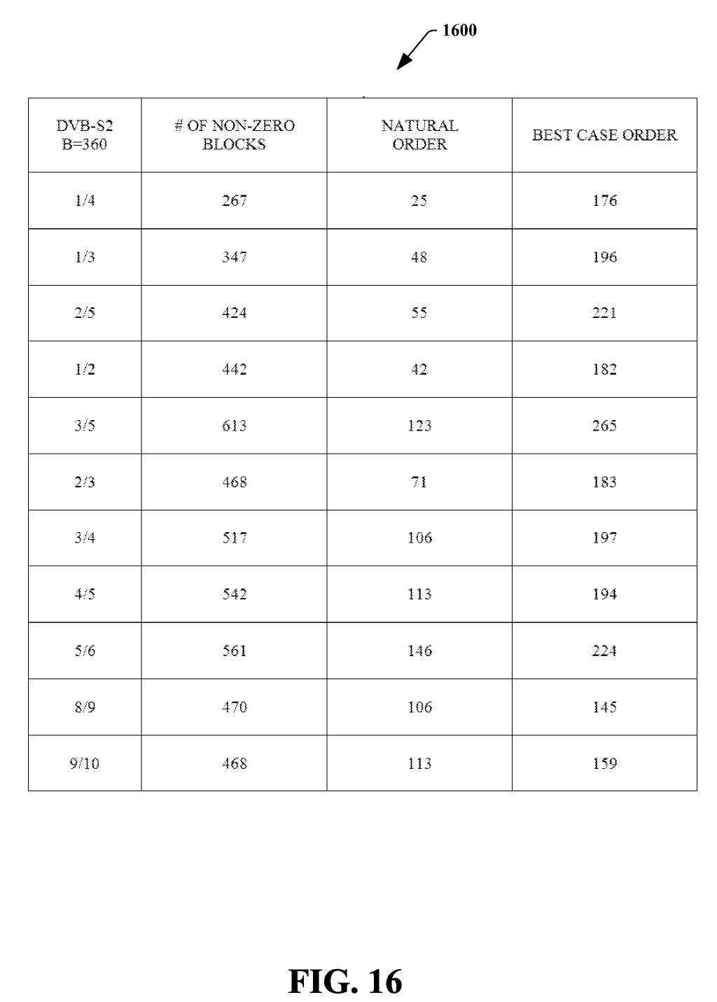

For example, FIGS. 14-16 tabulate the total number of overlapped columns considering three-layer overlapping for the LDPC codes, in which FIG. 14 tabulates total number of overlapped columns for the LDPC codes defined in IEEE 802.11n, FIG. 15 tabulates total number of the overlapped columns the LDPC codes defined in IEEE 802.16e, and FIG. 16 tabulates total number of the overlapped columns for the LDPC codes defined in IEEE DVB-S2. FIGS. 14-16 illustrate that for the small LDPC codes, the suboptimal algorithm (e.g., using simulated annealing) always converges to the optimal solution. For the large LDPC codes, like the codes used in DVB-S2 (e.g., FIG. 16), the suboptimal solutions are shown, and the simulated annealing does not always guarantee an optimal solution.

FIGS. 14-15 further illustrate that for codes used in IEEE 802.16e and IEEE 802.11n, 65.8%˜98.7% of access for the posterior reliability values (e.g., soft output values) in the Channel RAM can be bypassed. FIG. 16 illustrates that for the codes used in DVB-S2, 30.9%˜65.9% of access for the posterior reliability values (e.g., soft output values) for the systematic bits in the Channel RAM can be bypassed. Although a large amount of memory access can be reduced, as described above, the architecture of the traditional LDPC decoder has to be modified to implement memory-bypassing as further described below.

### LDPC Decoder Architecture Implementing Memory By-Passing

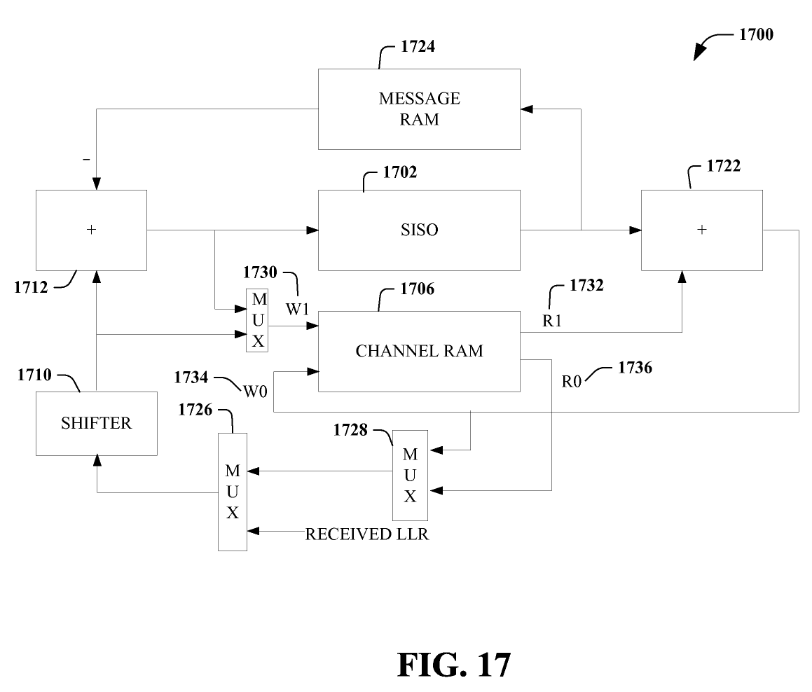

FIG. 17 depicts an exemplary non-limiting block diagram of a layered LDPC decoder 1700 with memory bypassing according to further non-limiting embodiments of the disclosed subject matter. For example, FIG. 17 can be utilized in a LDPC decoder for IEEE 802.11n LDPC code with sub-block size of 81 that implements memory bypassing according to the disclosed subject matter. LDPC decoder 1700 can utilize 81 SISO units 1702 in parallel to calculate multiple check nodes 108 processes for a layer. The operation of shifter 1710, sub-array 1712 and SISO 1702 can be described as discussed above regarding FIG. 4 (e.g., traditional layered decoding architectures). In order to minimize the memory access of the Channel RAM 1006, the order of the layers is determined by the algorithm describe above (e.g., a comprehensive algorithm, an algorithm that determines a path in an undirected graph with maximum cost, or an algorithm that utilizes a simulated annealing to determine the orders of the layers) and the like.

According to a further aspect of the disclosed subject matter, after determining the order of the layers, the order of the non-zero columns inside a layer can be determined based on, for example achieving a maximum amount overlapping of the messages and minimizing the idle cycles due to the data dependency of the layers.

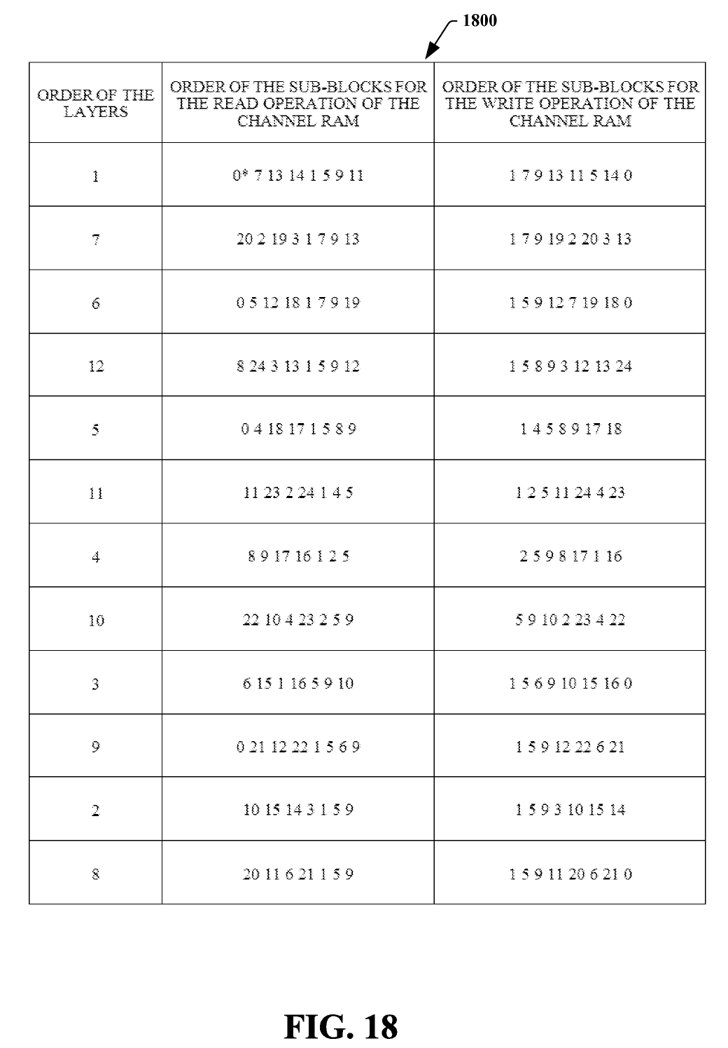

FIG. 18 tabulates an exemplary non-limiting order of the layers and the order of the sub-blocks in the layers for the LDPC decoders of FIG. 17, where “0*” indicates an idle operation. FIG. 18 shows the order of the layers processed by the decoder and the order of the non-zero columns (sub-blocks) in the layers for the read and write operation of the Channel RAM 1706 for the code rate ½ LDPC code. It can be seen that because the order of the sub-blocks for write operation for the memory storing the intermediate data (e.g., FIFO 1016) is the same as the order of the sub-blocks for read operation of the Channel RAM 1706, and that because the order of the sub-blocks for read operation for the memory storing the intermediate data (e.g., FIFO 1016) is the same as the order of the sub-blocks for write operation of the Channel RAM 1006, the orders of the sub-block for the memory storing the intermediate data (e.g., FIFO 1016) are not listed, and thus the FIFO is not shown in FIG. 17. Rather, in order to reduce the size of the memory (e.g., Message RAM 1724), the Channel RAM 1706 and the FIFO storing the intermediate data (e.g., FIFO 1016) in the traditional layered architecture can be merged according to various non-limiting embodiments (e.g., merged into a four port Channel RAM).

Thus, according to further non-limiting embodiments of the disclosed subject matter, a new Channel RAM 1706 can be used to store input LLR values of data initially received. In a further aspect, during the decoding, the Channel RAM 1706 can be used to store the intermediate results (e.g., 414) and posterior reliability (e.g., 408) values of the variable nodes 106. Accordingly, in particular non-limiting embodiments of the disclosed subject matter, Channel RAM 1706 can comprise, for example, six, four-port 24×81 bit synchronous RAM (SRAM)s. Because the messages for every variable node 106 will be either the intermediate results (e.g., 414) or the posterior reliability values (e.g., 408) during the decoding, each entry of the new Channel RAM 1706 can be dedicated to store the messages for the one sub-block in the base-matrix, according to further non-limiting embodiments.

For example, W1 port (1730) can used to store the results of Eqn. (9) and R1 port (1732) can be used to read the messages Γ_{m,n}^{(q+1)} out for the updating Eqn. (10), according to further aspects of the disclosed subject matter. It can be appreciated that if the updated results will be used in the decoding of the following two layers, it can be sent to shifter 1710 through the mux-array (e.g., 1726), and the write operation W0 and the read operation R0 can be disabled. Otherwise, the updated messages can be written into the Channel RAM 1706 through the write port W0 (1734) and the messages needed in the decoding can be read out through read port R0 (1736). According to further non-limiting embodiments of the disclosed subject matter, for LDPC codes with many overlapping layers, the four port Channel RAM 1706 can be reduced to dual-port memory by adding a small additional memory. For example, for IEEE 802.11n LDPC code with rate ⅚, one read and write operation in every iteration are not able to be bypassed. Thus, the read port R0 1736 and write port W0 1734 can be enabled once per iteration during the decoding.

Referring again to FIG. 17, according to further non-limiting embodiments of the disclosed subject matter, a bank of muxs (e.g., 1728) can be added to select the output of the Add-array 1712 and that of the Channel RAM 1706 and pipeline registers (not shown) can be added after the Add-array, in order to bypass the memory read and write operation. It can be appreciated that because the order of the messages entering the SISO 1702 (e.g., same order as the read order of the read port R0 (1736)) and the order of the messages updated in the Add-array 1722 (e.g., same order as the read order of the read port R1 (1732)) are different, the index generated (not shown) in the SISO 1702 indicating the position of the least reliable incoming messages will be incorrect for the update process. Thus, according to further non-limiting embodiments, a ROM (not shown) containing the order of the updated process (e.g., read order of the read port R1 (1732)) can be added and utilized together with the index generated (not shown) in the SISO 1702 to select the two magnitudes (not shown) for the update process. It can be appreciated that the overhead in die area and the power consumption is negligible and straightforward.

Thus, as a result of de-coupling the read and write order of the Channel RAM 1706, the number of read and write access of the Channel RAM 1706 after using memory bypassing per iteration can be achieved for the entire amount of overlapping listed in FIG. 14. Advantageously, when compared with the traditional design, depending on the LDPC codes, from 70.9% to approximately 98.7% of the memory access of the Channel RAM 1706 for the posterior reliability values (e.g., 408) of the variable nodes 106 during the decoding process can be achieved, according to various non-limiting embodiments of the disclosed subject matter. As a further advantage, the idle cycles due to the data dependency of messages can be minimized at the same time, according to various non-limiting embodiments of the disclosed subject matter.

### Experimental Results: Memory-Bypassing

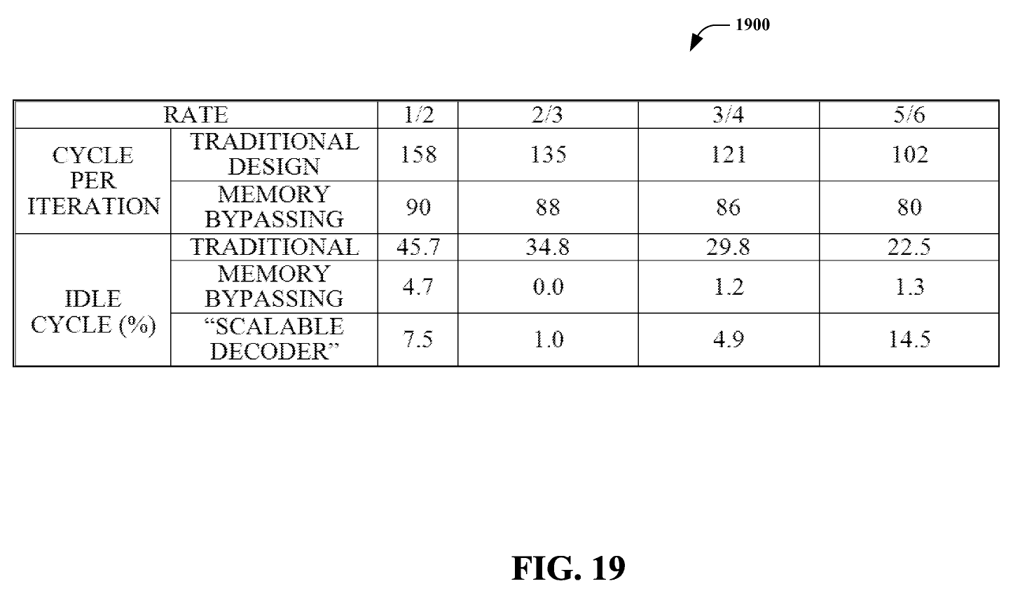

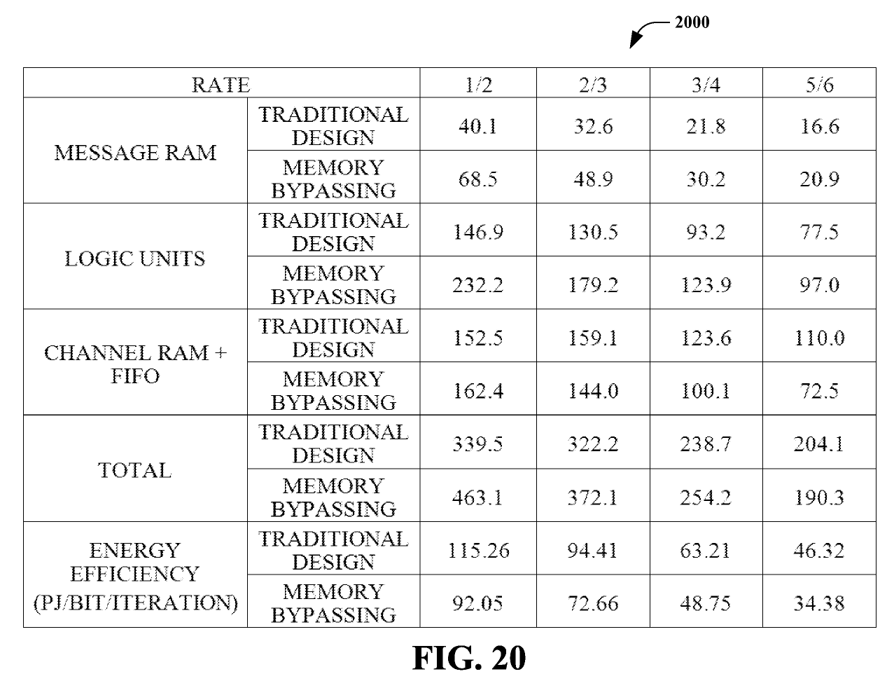

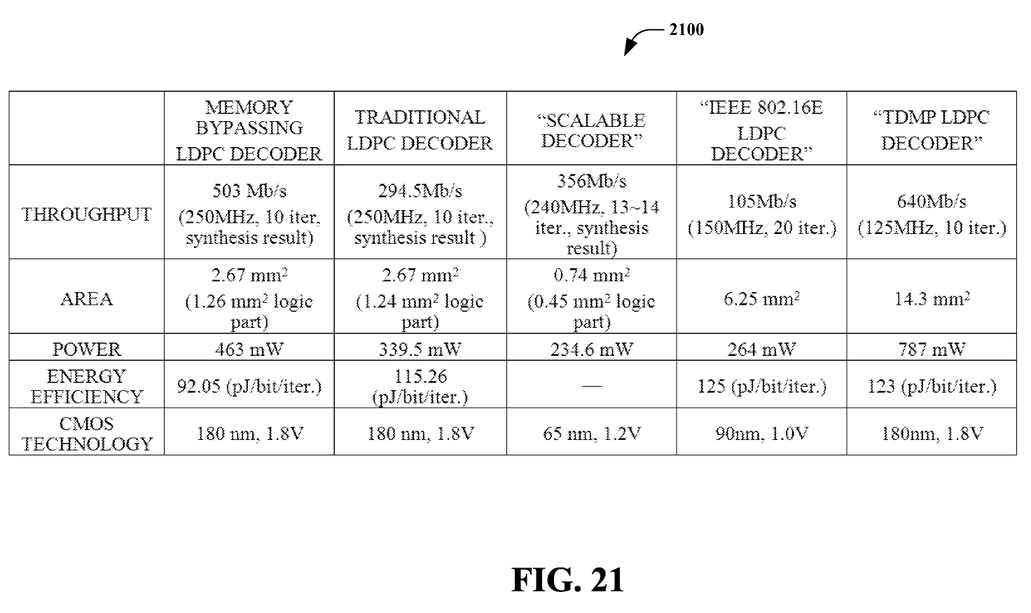

According to the descriptions of FIGS. 4 and 12-18 two particular non-limiting LDPC decoders for the IEEE 802.11n LDPC code were implemented and evaluated to demonstrate the power performance of exemplary implementations of the disclosed subject matter. FIGS. 19-21 tabulate performance of the various exemplary implementations of decoders, in which FIG. 19 tabulates clock cycles required per iteration and idle cycles in percentage 1900, FIG. 20 tabulates power consumption (in mW) of the two LDPC decoders 2000 when operated in 250 MHz and 10 iterations, and FIG. 21 tabulates further performance characteristics 2100 for the different LDPC decoder implementations.

The basic architecture for the traditional layered decoder is illustrated in FIG. 4 for an IEEE 802.11n standard using a 0.18 μm CMOS technology, and which has been implemented as a baseline for performance comparison. For both the particular non-limiting LDPC decoders and the traditional layered decoder, the bit-width for the soft output messages is set to be 6. The decoders were implemented and synthesized with Synopsys® (Design Compiler) using the Artisan's TSMC 0.18 μm standard cell library. The power consumption of the embedded SRAM is characterized by Simulation Program with Integrated Circuit Emphasis by Synopsys (HSPICE®) simulation with the TSMC® 0.18 μm process. The power consumption of the decoder was simulated using Synopsys® VCS-MX and PrimeTime®. The supply voltage is 1.8 Volt (V) and the clock frequency is 250 MegaHertz (MHz). The breakdown of the power consumption of the various components of the three decoders working in different code rate modes are tabulated in FIGS. 18-21.

FIG. 19 tabulates clock cycles required per iteration and idle cycles in percentage which summarizes the comparison in clock cycles required per iteration and idle cycles for the two decoders and a further design by Rovini et al., “A Scalable Decoder Architecture for IEEE 802.11n LDPC Codes”, Global Telecommunications Conference (GLOBECOM '07), 2007, November 2007 (hereinafter, “Scalable Decoder”). Compared with the traditional decoder using natural order, the decoding using the memory bypassing scheme and read-write de-coupling the read and write order of the memory can reduce the idle cycles from 21.2% to approximately 40%. Compared with the Scalable Decoder, the idle cycle is reduced from 1% to approximately 13.2%. The idle clock cycle in the decoder using memory bypassing scheme is only due to the irregular check node 108 degrees. Advantageously, the disclosed subject matter can eliminate the data dependency issue (e.g., the updated message is computed before it is being needed for another layer), which can hinder the layered decoding architecture application to the standardized codes.

FIG. 20 tabulates power consumption (in mW) of the two LDPC decoders when operated in 250 MHz and 10 iterations. Because clock cycles required per iteration for the two decoders are different, the power consumption breakdowns and the energy efficiency of the two decoders working at different code rate mode are tabulated in FIG. 20 for comparison. It can be seen that the decoder using memory bypassing reduces the energy consumption from 20.1% to approximately 25.8% depending on the LDPC codes.

FIG. 21 tabulates further performance characteristics for different LDPC decoder implementations that have been studied including the “Scalable Decoder”, a design by Mansour and Shanbhag, “A 640-Mb/s 2048-bit programmable LDPC decoder chip,” IEEE Journal of Solid-State Circuits, vol. 41, no. 3, pp. 684-698, March 2006 (hereinafter, “TDMP LDPC Decoder”), and a design by Liu et al., “An LDPC Decoder Chip Based on Self-Routing Network for IEEE 802.16e Applications”, IEEE Journal of Solid-State Circuits, vol. 43, pp. 684-694, March 2008 (hereinafter, “802.16e LDPC Decoder”).

### Low Power Layered Decoding for Low Density Parity Check Using Memory Bypassing and Thresholding

For LDPC decoding, it can be shown that the magnitudes of the outgoing messages for the variable nodes 106 are typically determined in large part by the two smallest values in a check node 108. For example, it can be shown that min-sum and its variants (e.g., like offset min-sum) work for this reason. Thus, for decoding architecture using fix point computation, as the decoding proceeds, it can be appreciated that the soft values can begin to saturate at the maximum number that can be represented by the bit-width of the architecture. As a result, the check-to-variable messages can mainly be determined by the smaller soft output messages (e.g., output of 422/1022 (408), not labeled in FIG. 10).

In addition, if the value of the soft message (e.g., output of 422/1022 (408), not labeled in FIG. 10) is very large, the sensitivity of the decoding performance with respect to the actual value can become smaller. As a result, various embodiments of the disclosed subject matter can clip the maximum value of the soft value to a threshold value, to limit the performance degradation to reasonable levels. Thus, in further aspects of the disclosed subject matter, the provided decoders can use a thresholding scheme that clips or otherwise limits the maximum value of the soft message (e.g., output of 422/1022 (408), not labeled in FIG. 10) to a threshold value.

FIG. 22 illustrates an exemplary non-limiting block diagram of LDPC decoders 2200 with memory bypassing and thresholding. It should be appreciated that the similarly named components of FIG. 22 can have similarly described functionality as described above regarding FIGS. 4 and 10, except as noted below. In addition, it should be appreciated that the presently described aspects of the disclosed subject matter are suitably incorporated into the previously described decoders. Thus, the provided decoders 2200 can determine whether the magnitude of the intermediate soft message (e.g., output of 422/1022/2222 (408), not labeled in FIGS. 10 and 22) is larger than or equal to a threshold value T 2230 (e.g., a preset threshold value, an iteratively determined threshold value, etc.). In response to the determination, the provided decoders 2200 can ignore the magnitude part and can cause the magnitude part to not be read and/or stored in FIFO (e.g., 416/1016/2216) during the decoding. In a further aspect of the disclosed subject matter, the provided decoders 2200 can include another memory called a threshold memory 2232, and a bit S (not shown) can be written to the threshold memory to indicate that the value of the soft message (e.g., output of 422/1022/2222 (408), not labeled in FIGS. 10 and 22) is larger than the threshold 2230. For example, according to various non-limiting embodiments of the disclosed subject matter if:

|Γ_{m,n}^{q+1)}|=|Λₙ^{(q+1)}[k−1]−R_{m,n}^{(q)}|≧T (12)

the decoders 2200 can indicate that the value of the soft message (e.g., output of 422/1022/2222 (408), not labeled in FIGS. 10 and 22) is larger than the threshold bit S by writing the sign bit (not shown) into the threshold memory 2232 and FIFO (e.g., 416/1016/2216).

Thus, according to further aspects of the disclosed subject matter, during calculation of Eqn. (8) in the SISO (e.g., 402/1002/2202), the preset threshold value T 2230 can be used in place of the value of the soft message (e.g., output of 422/1022/2222 (408), not labeled in FIGS. 10 and 22). Accordingly, embodiments of the disclosed subject matter can thereby advantageously reduce the amount of read/write access operation for the FIFO (e.g., 416/1016/2216) in addition to reducing the amount of read/write access operation for the Channel RAM (e.g., 406/1006/2206). In addition, it should be appreciated that even by choosing a bit-width for the intermediate value (e.g., output of 422/1022/2222 (408), not labeled in FIGS. 10 and 22) that is relatively small (e.g., 6 bits in exemplary non-limiting embodiments using one bit for sign and the others for the magnitude) the overhead to write the bit S per data can be quite large.

Thus, according to further non-limiting aspects, various implementations of the disclosed subject matter can combine two S bits (not shown) together in order to reduce the overhead in writing the bit S per data. For example, if the magnitudes of two intermediate messages (e.g., output of 422/1022/2222 (408), not labeled in FIGS. 10 and 22) are larger than the threshold value T 2230, a single bit S (not shown) can be written to the threshold memory 2232 to indicate that both of these two messages are larger than the threshold 2230. Thus, according to further aspects of the disclosed subject matter, the magnitudes of these two messages will not be written into FIFO (e.g., 416/1016/2216).

According to further aspects, the disclosed decoders 2200 can first access a threshold memory 2232 first during the updating process, to determine whether bit S (not shown) for the two messages indicate that the two messages are larger than the threshold 2230 (e.g., bit S (not shown) for the two messages are ‘1’). Accordingly, on this basis, the two messages can be determined to be larger than the threshold 2230. Based on this determination the provided decoders can avoid accessing the memory and can avoid storing the magnitude part of the two messages. As a result, the maximum number that can be represented by the bit-width of the architecture can be used for the Adder-array (e.g., 422/1022/2222) to carry out the update process. Otherwise, if the two messages are determined to be not larger than the threshold 2230, the provided decoders 2200 can read the memory (e.g., 416/1016/1216) storing the magnitude part of the two messages, which can be sent to the Adder-array (e.g., 422/1022/2222).

It can be appreciated that the threshold value T 2230 can affect the error-correcting performance as well as the amount of memory access. Thus, according to various aspects of the disclosed subject matter, a small threshold value T 2230 can degrade the error-correcting performance, while a large threshold value T 2230 can result in smaller reduction of the memory access. Thus, the proper threshold value T 2230 can be determined through simulation to obtain the optimal trade-off between the performance and the power consumption. For example, according to exemplary non-limiting embodiments of the disclosed subject matter, the threshold value T 2230 determined through simulation (e.g., T=21) proved to be an acceptable trade-off. While a singular threshold 2230 has been described in reference to the disclosed embodiments, it is contemplate that various non-limiting embodiments of the disclosed subject matter can employ feedback mechanisms to iteratively or dynamically determine the threshold value. For example, an iteratively or dynamically determined threshold value can be based on, for example, a determined or specified error-correction performance parameter (e.g., determined or specified error rate), a power usage or reduction requirement or performance parameter (e.g., a power usage specification or indication), a decoding mode switch (e.g., from rate ½ to rate ¾, etc.), and/or other design parameters or operating parameters (e.g., power management schemes) so on.

FIG. 23 depicts the decoding performance 2300 of particular non-limiting embodiments (e.g., rate ⅚ LDPC code) in terms of frame error rate (-) and bit error rate (--) of the different decoding algorithms. From FIG. 23, it can be seen the degradation in performance using thresholding is insignificant when compared with the fixed point design.

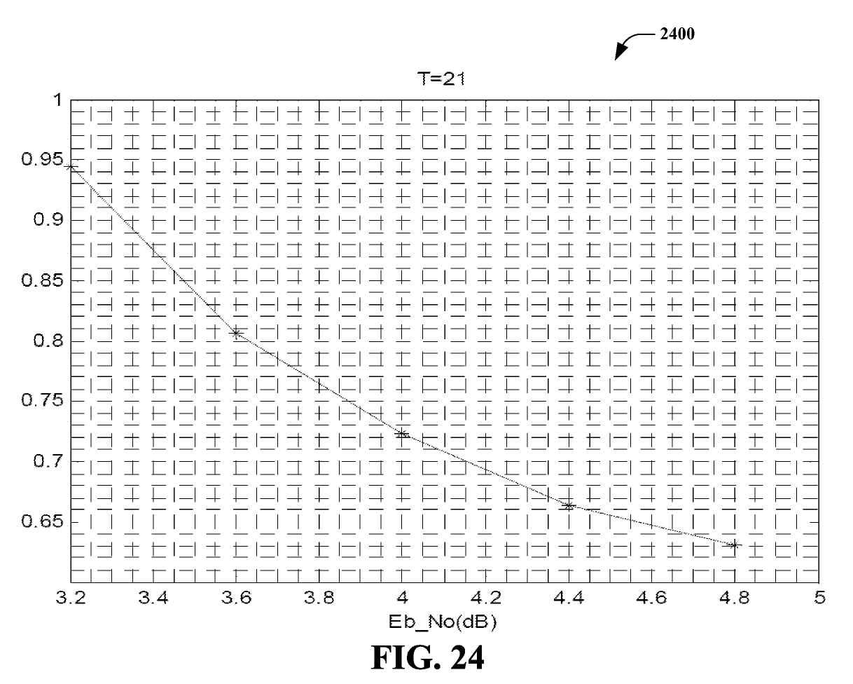

FIG. 24 depicts simulation results 1400 of normalized memory access (in terms of # of bit read and write) of FIFO (e.g., 416/1016/2216) for rate ⅚ LDPC code defined in IEEE 802.11n. The memory access includes both the FIFO (e.g., 416/1016/2216) and threshold memory 2232 access. From FIG. 24, it can be seen that with different Signal to Noise Ratio (SNR) values, the amount of memory access can be reduced from 5% to approximately 37%. In addition, it can be seen that when the SNR is higher, during the decoding iteration, the soft message values become more reliable and more values saturate with large values. Thus, according to various non-limiting embodiments, the disclosed subject matter can provide further reductions in the amount of memory access operations as more values are larger than the threshold.

It is to be appreciated that the provided embodiments are exemplary and non-limiting implementations of the techniques provided by the disclosed subject matter. As a result, such examples are not intended to limit the scope of the hereto appended claims. For example, certain system consideration or design-tradeoffs are described for illustration only and are not intended to imply that other parameters or combinations thereof are not possible or desirable. Accordingly, such modifications as would be apparent to one skilled in the are intended to fall within the scope of the hereto appended claims.

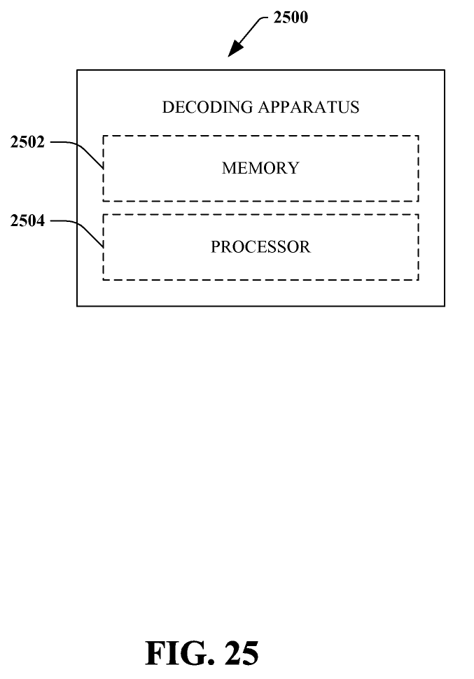

FIG. 25 illustrates an exemplary non-limiting decoding apparatus suitable for performing various techniques of the disclosed subject matter. The apparatus 2500 can be a stand-alone decoding apparatus or portion thereof or a specially programmed computing device or a portion thereof (e.g., a memory retaining instructions and/or data for performing the techniques as described herein coupled to a processor). Apparatus 1500 can include a memory 2502 that retains various instructions and/or data with respect to decoding, performing comparisons and/or determinations, statistical calculations, analytical routines, and/or the like. For instance, apparatus 2500 can include a memory 2502 that retains instructions determining optimal decoding order (e.g., executing a search algorithm to determine an optimal order of the layers such as a comprehensive algorithm, an algorithm that determines a path in an undirected graph with maximum cost, or an algorithm that utilizes a simulated annealing to determine the orders of the layers, and the like) as described above regarding FIGS. 4, 10, 17 and 22, for example. The memory 2502 can further retain instructions for scheduling decoding order. Additionally, memory 2502 can retain instructions for maximizing layer overlap for instance by decoupling memory read/write operations. Memory 2502 can further include instructions pertaining to bypassing memory read and/or write operations and/or performing threshold determinations associated with a thresholding techniques. The above example instructions and other suitable instructions and/or data can be retained within memory 2502, and a processor 2504 can be utilized in connection with executing the instructions.

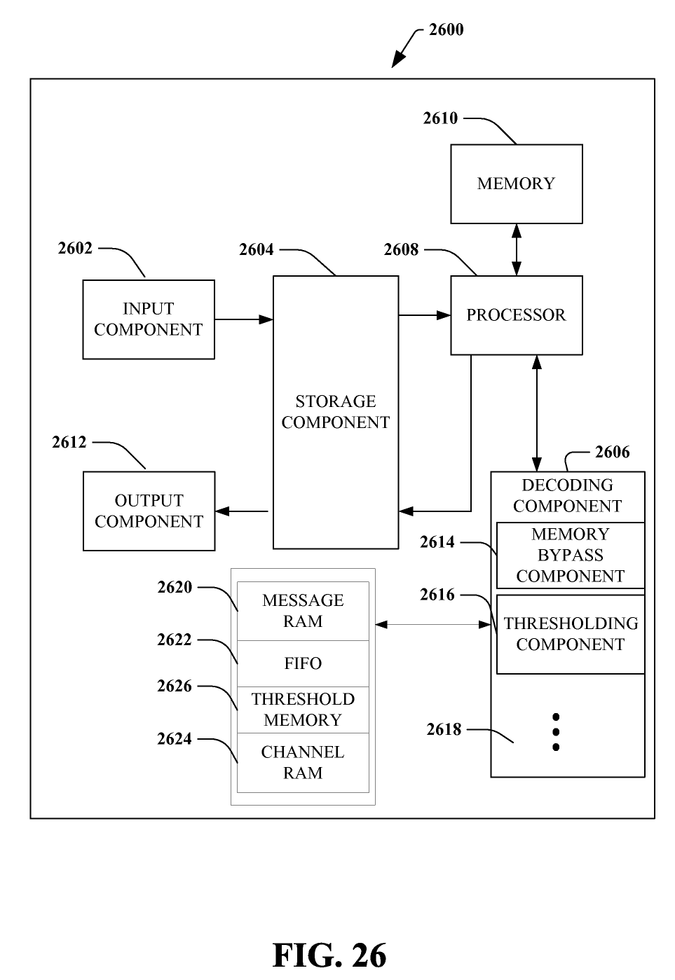

FIG. 26 illustrates a system 2600 that can be utilized in connection with the low power LDPC decoders as described herein. System 2600 comprises an input component 2602 that receives data or signals for decoding, and performs typical actions on (e.g., transmits to storage component 2604 or other components such as decoding component 2606) the received data or signal. A storage component 2604 can store the received data or signal for later processing or can provide it to decoding component 2606, or processor 2608, via memory 2610 over a suitable communications bus or otherwise, or to the output component 2612.

Processor 2608 can be a processor dedicated to analyzing information received by input component 2602 and/or generating information for transmission by an output component 2612. Processor 2608 can be a processor that controls one or more portions of system 2600, and/or a processor that analyzes information received by input component 2602, generates information for transmission by output component 2612, and performs various decoding algorithms as described herein, or portions thereof, of decoding component 2606. System 2600 can include a decoding component 2606 that can perform the various techniques as described herein, in addition to the various other functions required by the decoding context (e.g., computing an optimal decoding order, executing a search algorithm to determine an optimal order of the layers such as executing a comprehensive algorithm, executing an algorithm that determines a path in an undirected graph with maximum cost, or executing an algorithm that utilizes a simulated annealing to determine the orders of the layers, and the like, layer scheduling, memory bypassing, threshold determinations, etc.).

Decoding component 2606 can include plurality of muxs (not shown) and/or one or more pipeline registers (not shown), for example as part of a memory bypass component 2614 that bypasses a memory write operation and a memory read operation for the channel RAM to directly the pass soft output values of the variable node 106 when two consecutive layers have overlapping columns. In addition, memory bypass component 2614 can comprise a scheduling component (not shown) that schedules a decoding order to maximize the number of overlapping columns between two consecutive layers to be decoded. For example, the scheduling component can determine and optimal decoding order of the two consecutive layers by determining a decoupled order of sub-blocks to be updated within at least one of the layers.

Thus, decoding component 2606 can be configured to determine an optimal decoding order and/or schedule a decoding order to facilitate bypassing memory access operations as described herein. Additionally, decoding component 2606 can include a thresholding component 2616 that can be configured to perform threshold determinations associated with thresholding techniques as described herein. For example, the thresholding component 2616 can determine whether the soft output values exceed a preset threshold and can replace the soft output values with the preset threshold prior to storage in the channel RAM if the soft output values exceed the preset threshold.

In addition, decoding component 2606 can include 2618 one or more of add-array (not shown), sub-array (not shown), shifter (not shown), ROMs (not shown), and/or SISO (not shown), as described in further detail above in connection with FIGS. 4, 10, 17 and 22. While decoding component 2606 is shown external to the processor 2608 and memory 2610, it is to be appreciated that decoding component 2606 can include decoding code stored in storage component 2604 and subsequently retained in memory 2610 for execution by processor 2606 to perform the techniques described herein, or portions thereof In addition, it can be appreciated, that the decoding code can utilize artificial intelligence based methods in connection with performing inference and/or probabilistic determinations and/or statistical-based determinations in connection applying the decoding techniques described herein.

System 2600 can additionally comprise memory 2610 that is operatively coupled to processor 2608 and that stores information such as described above, parameters, information, and the like, wherein such information can be employed in connection with implementing the decoder techniques as described herein. Memory 2610 can additionally store protocols associated with generating lookup tables, etc., such that system 2600 can employ stored protocols and/or algorithms further to the performance of memory bypassing and/or thresholding.

In addition, system 2600 can include a message RAM 2620, memory for intermediate date (e.g., FIFO) 2622, Channel RAM 2624, registers (not shown), and/or threshold memory 2626 as described in further detail above in connection with FIGS. 4, 10, 17 and/or 22. It will be appreciated that storage component 2604 and/or memory 2610 or any combination thereof as described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), or flash memory. Volatile memory can include random access memory (RAM), which acts as cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus® RAM (DRRAM). The memory 2610 is intended to comprise, without being limited to, these and any other suitable types of memory, including processor registers and the like. In addition, by way of illustration and not limitation, storage component 2604 can include conventional storage media as in known in the art (e.g., hard disk drive).

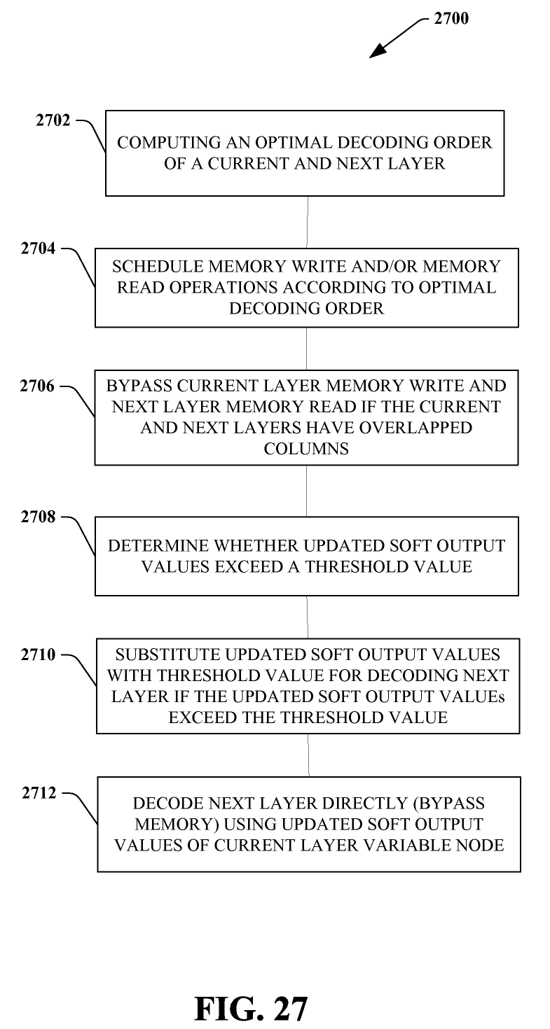

FIG. 27 illustrates a non-limiting block diagram illustrating exemplary high level methodologies 2700 according to various aspects of the disclosed subject matter. According to various non-limiting embodiments of the disclosed subject matter, at 2702 an optimal decoding order of the layers can be computed. For example, an optimal decoding order of the layers can be computed by determining a decoupled order of sub-blocks to be updated within at least one of the layers, as described above. As a further example, a decoupled order of sub-blocks to be updated can be determined based on whether a memory write operation for a column of the current layer can occur concurrently with a read operation of a column of the next layer to create an overlapped column (e.g. the occurrence of two consecutive layers that have non-null matrix 308 at the same column). Computing an optimal decoding can comprise executing a search algorithm to determine an optimal order of the layers, where executing a search algorithm can include such as a comprehensive search algorithm, an executing a search algorithm that determines a path in an undirected graph with maximum cost, or executing an algorithm that utilizes a simulated annealing to determine the orders of the layers, and the like

At 2704, at least one of the memory write operation or the memory read operation can be scheduled according to the optimal decoding order, thereby producing at least one overlapped column. For instance, a determination can be made (not shown) as to whether both of a current layer and a next layer have a non-null matrix at a column where the current layer overlaps the next layer (e.g., an overlapped column).

For example, at 2706 a memory write operation for the current layer and a memory read operation for the next layer can be bypassed if the current layer memory write operation and the next layer memory read operation have overlapped columns. As a result, bypassing the current layer memory write operation and the next layer memory read operation (e.g., bypassing the Channel memory 406/1006/2206) can facilitate decoding the next layer directly using updated soft output (e.g., posterior reliability) values of a variable node 106 of the current layer. For example, the next layer can be decoded directly by generating two outgoing message magnitudes for a check node 108 of the next layer from two of incoming messages having smallest magnitudes for the variable node 106 and from a soft-input-soft-output unit generated index for the decoupled order of sub-blocks to be updated within at least one of the layers. As a further example, the two outgoing message magnitudes can be computer using any of a min-sum approximation algorithm, an offset min-sum algorithm, or a two-output approximation algorithm.

At 2708, a determination can be made as to whether the updated posterior reliability values exceeds a threshold value 2230. Thus, at 2710 the updated soft output (e.g., posterior reliability) values 408 can be substituted with the threshold value 2230 in decoding the next layer directly based on the determination. In addition, a bit can be written to a threshold memory 2232 in lieu of the memory write operation to Channel memory (e.g., 2206) for the current layer to indicate that the value of the updated posterior reliability values exceed the threshold value 2230. For instance, a threshold value 2230 can be iteratively determined the based on a determined error-correction performance parameter, a specified error-correction performance parameter, a power usage requirement, a power reduction requirement, a power reduction performance parameter, or a power reduction scheme or any combination.

### Experimental Results: Memory-Bypassing and Thresholding

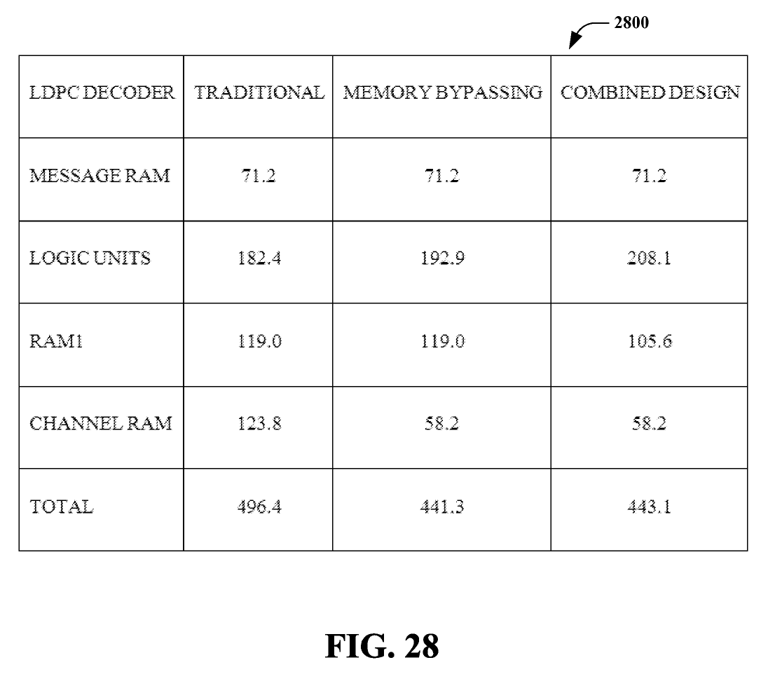

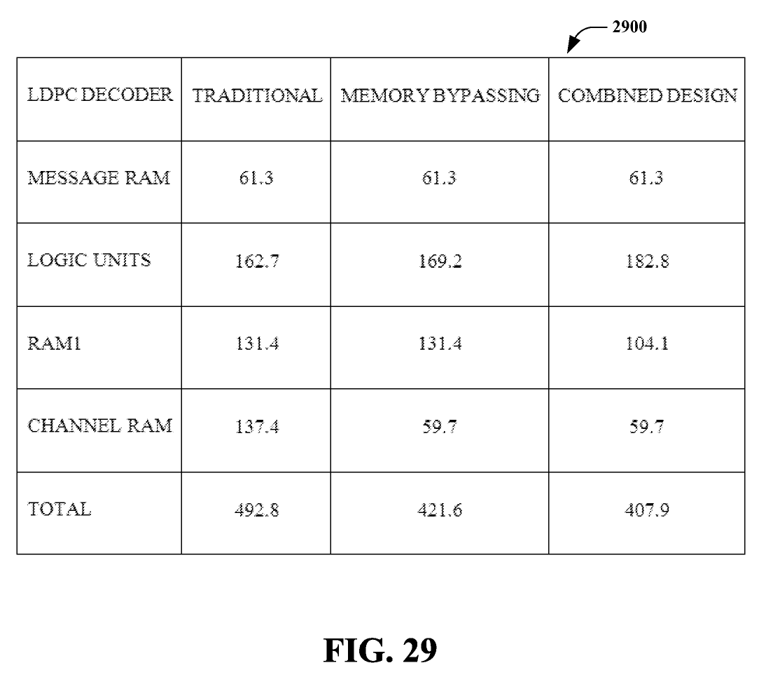

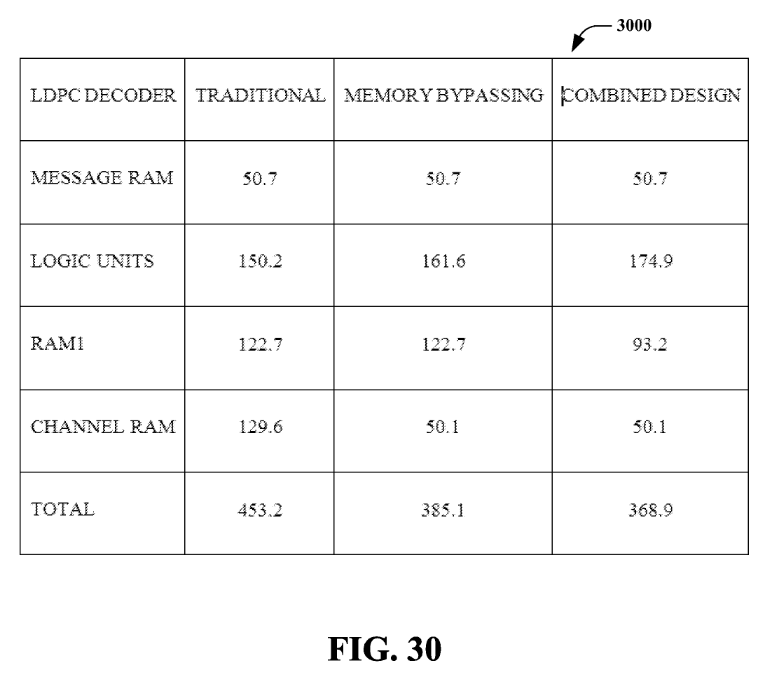

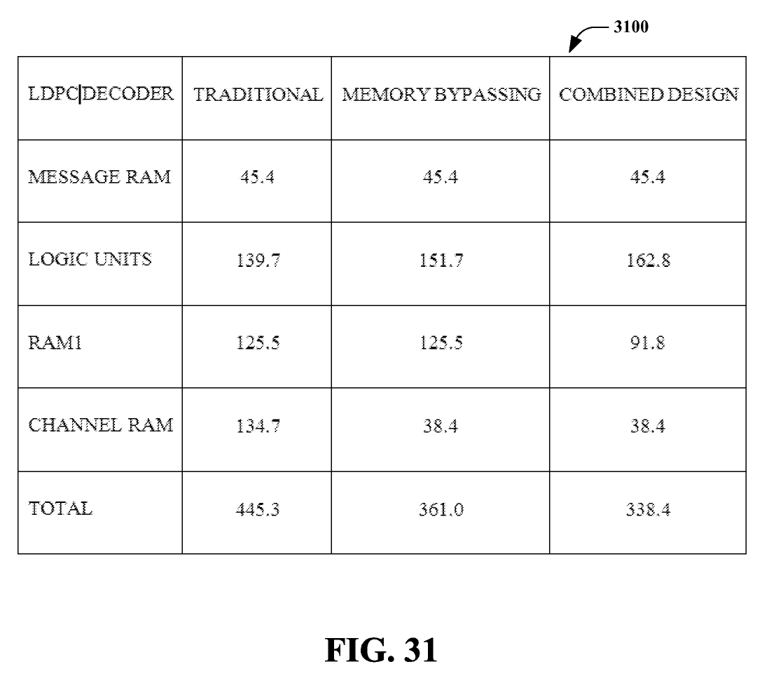

According to the descriptions of FIGS. 10-11 and 22-24, three particular non-limiting LDPC decoders for the IEEE 802.11n LDPC code were implemented and evaluated to demonstrate the power performance of exemplary implementations of the disclosed subject matter. FIGS. 28-31 tabulate power consumption (in mW) of the three particular non-limiting LDPC decoders, a traditional layered decoding architecture of FIG. 4, a layered decoding architecture with memory bypassing, and a layered decoding architecture combining both memory bypassing and thresholding, in which: FIG. 28 tabulates power consumption 2800 when operated in rate ½ mode; FIG. 29 tabulates power consumption 2900 when operated in rate ⅔ mode; FIG. 30 tabulates power consumption 3000 when operated in rate ¾ mode; and FIG. 31 tabulates power consumption 3100 when operated in rate ⅚ mode.

The basic architecture for the traditional layered decoder is illustrated in FIG. 4 for an IEEE 802.11n standard using a 0.18 μm CMOS technology, and which has been implemented as a baseline for performance comparison. In addition, the partial-parallel architecture uses 81 SISO. For the three particular non-limiting LDPC decoders, the bit-width for the soft output messages is set to be 6. The decoders were implemented and synthesized with Synopsys® (Design Compiler) using the Artisan's TSMC 0.18 μm standard cell library. The power consumption of the embedded SRAM is characterized by HSPICE® simulation with the TSMC® 0.18 μm process. The power consumption of the decoder was simulated using Synopsys® VCS-MX and PrimeTimeφ at the SNR achieving a frame error rate around 10⁻³. The supply voltage is 1.8 V and the clock frequency is 200 MHz. The breakdown of the power consumption of the various components of the three decoders working in different code rate modes are tabulated in FIGS. 28-31.

From FIGS. 28-31, it can be seen that from 53% to approximately 72% of the power consumption of the Channel RAM (e.g., 406/1006/2206) can be reduced using memory bypassing (e.g., FIGS. 10 and 22). Advantageously, the resultant increase in power overhead is reflected in the increase in power of the logic units is relatively small. At the same time, using thresholding (e.g., FIG. 22), the power consumption of the FIFO (e.g., 416/1016/2216) is reduced by 11%˜27%. For code rate=½, the resultant increase in power overhead in the logic unit is about the same as the power saving in FIFO (e.g., 416/1016/2216). For other code rate, the power saving of FIFO (e.g., 416/1016/2216) exceeds the resultant increase in power overhead. Advantageously, when both memory bypassing and thresholding are implemented together (e.g., FIG. 22), the total power consumption of the LDPC decoder is reduced by 11%˜24% depending on the code rate.

### Exemplary Computer Networks and Environments

One of ordinary skill in the art can appreciate that the disclosed subject matter can be implemented in connection with any computer or other client or server device, which can be deployed as part of a communications system, a computer network, or in a distributed computing environment, connected to any kind of data store. In this regard, the disclosed subject matter pertains to any computer system or environment having any number of memory or storage units, and any number of applications and processes occurring across any number of storage units or volumes, which may be used in connection with communication systems using the decoder techniques, systems, and methods in accordance with the disclosed subject matter. The disclosed subject matter may apply to an environment with server computers and client computers deployed in a network environment or a distributed computing environment, having remote or local storage. The disclosed subject matter may also be applied to standalone computing devices, having programming language functionality, interpretation and execution capabilities for generating, receiving and transmitting information in connection with remote or local services and processes.

Distributed computing provides sharing of computer resources and services by exchange between computing devices and systems. These resources and services include the exchange of information, cache storage and disk storage for objects, such as files. Distributed computing takes advantage of network connectivity, allowing clients to leverage their collective power to benefit the entire enterprise. In this regard, a variety of devices may have applications, objects or resources that may implicate the communication systems using the decoder techniques, systems, and methods of the disclosed subject matter.

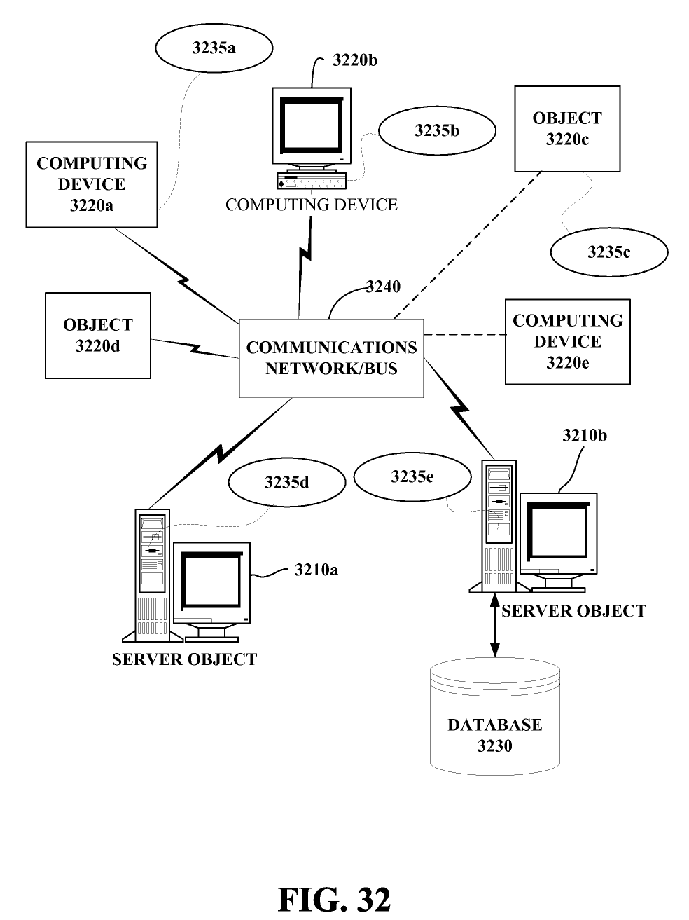

FIG. 32 provides a schematic diagram of an exemplary networked or distributed computing environment. The distributed computing environment comprises computing objects 3210a, 3210b, etc. and computing objects or devices 3220a, 3220b, 3220c, 3220d, 3220e, etc. These objects may comprise programs, methods, data stores, programmable logic, etc. The objects may comprise portions of the same or different devices such as PDAs, audio/video devices, MP3 players, personal computers, etc. Each object can communicate with another object by way of the communications network 3240. This network may itself comprise other computing objects and computing devices that provide services to the system of FIG. 32, and may itself represent multiple interconnected networks. In accordance with an aspect of the disclosed subject matter, each object 3210a, 3210b, etc. or 3220a, 3220b, 3220c, 3220d, 3220e, etc. may contain an application that might make use of an API, or other object, software, firmware and/or hardware, suitable for use with the design framework in accordance with the disclosed subject matter.

It can also be appreciated that an object, such as 3220c, may be hosted on another computing device 3210a, 3210b, etc. or 3220a, 3220b, 3220c, 3220d, 3220e, etc. Thus, although the physical environment depicted may show the connected devices as computers, such illustration is merely exemplary and the physical environment may alternatively be depicted or described comprising various digital devices such as PDAs, televisions, MP3 players, etc., any of which may employ a variety of wired and wireless services, software objects such as interfaces, COM objects, and the like.

There are a variety of systems, components, and network configurations that support distributed computing environments. For example, computing systems may be connected together by wired or wireless systems, by local networks or widely distributed networks. Currently, many of the networks are coupled to the Internet, which provides an infrastructure for widely distributed computing and encompasses many different networks. Any of the infrastructures may be used for communicating information used in the communication systems using the decoder techniques, systems, and methods according to the disclosed subject matter.

The Internet commonly refers to the collection of networks and gateways that utilize the Transmission Control Protocol/Internet Protocol (TCP/IP) suite of protocols, which are well-known in the art of computer networking. The Internet can be described as a system of geographically distributed remote computer networks interconnected by computers executing networking protocols that allow users to interact and share information over network(s). Because of such wide-spread information sharing, remote networks such as the Internet have thus far generally evolved into an open system with which developers can design software applications for performing specialized operations or services, essentially without restriction.

Thus, the network infrastructure enables a host of network topologies such as client/server, peer-to-peer, or hybrid architectures. The “client” is a member of a class or group that uses the services of another class or group to which it is not related. Thus, in computing, a client is a process, e.g., roughly a set of instructions or tasks, that requests a service provided by another program. The client process utilizes the requested service without having to “know” any working details about the other program or the service itself. In a client/server architecture, particularly a networked system, a client is usually a computer that accesses shared network resources provided by another computer, e.g., a server. In the illustration of FIG. 32, as an example, computers 3220a, 3220b, 3220c, 3220d, 3220e, etc. can be thought of as clients and computers 3210a, 3210b, etc. can be thought of as servers where servers 3210a, 3210b, etc. maintain the data that is then replicated to client computers 3220a, 3220b, 3220c, 3220d, 3220e, etc., although any computer can be considered a client, a server, or both, depending on the circumstances. Any of these computing devices may be processing data or requesting services or tasks that may use or implicate the communication systems using the decoder techniques, systems, and methods in accordance with the disclosed subject matter.

A server is typically a remote computer system accessible over a remote or local network, such as the Internet or wireless network infrastructures. The client process may be active in a first computer system, and the server process may be active in a second computer system, communicating with one another over a communications medium, thus providing distributed functionality and allowing multiple clients to take advantage of the information-gathering capabilities of the server. Any software objects utilized pursuant to communication (wired or wirelessly) using the decoder techniques, systems, and methods of the disclosed subject matter may be distributed across multiple computing devices or objects.

Client(s) and server(s) communicate with one another utilizing the functionality provided by protocol layer(s). For example, HyperText Transfer Protocol (HTTP) is a common protocol that is used in conjunction with the World Wide Web (WWW), or “the Web.” Typically, a computer network address such as an Internet Protocol (IP) address or other reference such as a Universal Resource Locator (URL) can be used to identify the server or client computers to each other. The network address can be referred to as a URL address. Communication can be provided over a communications medium, e.g., client(s) and server(s) may be coupled to one another via TCP/IP connection(s) for high-capacity communication.

Thus, FIG. 32 illustrates an exemplary networked or distributed environment, with server(s) in communication with client computer (s) via a network/bus, in which the disclosed subject matter may be employed. In more detail, a number of servers 3210a, 3210b, etc. are interconnected via a communications network/bus 3240, which may be a LAN, WAN, intranet, GSM network, the Internet, etc., with a number of client or remote computing devices 3220a, 3220b, 3220c, 3220d, 3220e, etc., such as a portable computer, handheld computer, thin client, networked appliance, or other device, such as a VCR, TV, oven, light, heater and the like in accordance with the disclosed subject matter. It is thus contemplated that the disclosed subject matter may apply to any computing device in connection with which it is desirable to communicate data over a network.

In a network environment in which the communications network/bus 3240 is the Internet, for example, the servers 3210a, 3210b, etc. can be Web servers with which the clients 3220a, 3220b, 3220c, 3220d, 3220e, etc. communicate via any of a number of known protocols such as HTTP. Servers 3210a, 3210b, etc. may also serve as clients 3220a, 3220b, 3220c, 3220d, 3220e, etc., as may be characteristic of a distributed computing environment.

As mentioned, communications to or from the systems incorporating the decoder techniques, systems, and methods of the disclosed subject matter may ultimately pass through various media, either wired or wireless, or a combination, where appropriate. Client devices 3220a, 3220b, 3220c, 3220d, 3220e, etc. may or may not communicate via communications network/bus 3240, and may have independent communications associated therewith. For example, in the case of a TV or VCR, there may or may not be a networked aspect to the control thereof. Each client computer 3220a, 3220b, 3220c, 3220d, 3220e, etc. and server computer 3210a, 3210b, etc. may be equipped with various application program modules or objects 3235a, 3235b, 3235c, etc. and with connections or access to various types of storage elements or objects, across which files or data streams may be stored or to which portion(s) of files or data streams may be downloaded, transmitted or migrated. Any one or more of computers 3210a, 3210b, 3220a, 3220b, 3220c, 3220d, 3220e, etc. may be responsible for the maintenance and updating of a database 3230 or other storage element, such as a database or memory 3230 for storing data processed or saved based on communications made according to the disclosed subject matter. Thus, the disclosed subject matter can be utilized in a computer network environment having client computers 3220a, 3220b, 3220c, 3220d, 3220e, etc. that can access and interact with a computer network/bus 3240 and server computers 3210a, 3210b, etc. that may interact with client computers 3220a, 3220b, 3220c, 3220d, 3220e, etc. and other like devices, and databases 3230.

### Exemplary Computing Device

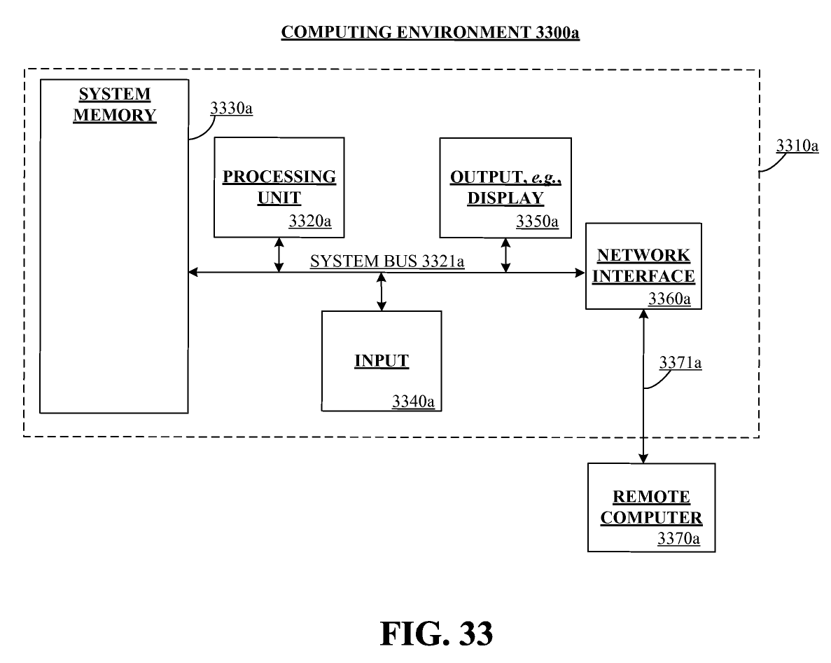

As mentioned, the disclosed subject matter applies to any device wherein it may be desirable to communicate data, e.g., to or from a mobile device. It should be understood, therefore, that handheld, portable and other computing devices and computing objects of all kinds are contemplated for use in connection with the disclosed subject matter, e.g., anywhere that a device may communicate data or otherwise receive, process or store data. Accordingly, the below general purpose remote computer described below in FIG. 33 is but one example, and the disclosed subject matter may be implemented with any client having network/bus interoperability and interaction. Thus, the disclosed subject matter may be implemented in an environment of networked hosted services in which very little or minimal client resources are implicated, e.g., a networked environment in which the client device serves merely as an interface to the network/bus, such as an object placed in an appliance.

Although not required, the some aspects of the disclosed subject matter can partly be implemented via an operating system, for use by a developer of services for a device or object, and/or included within application software that operates in connection with the component(s) of the disclosed subject matter. Software may be described in the general context of computer-executable instructions, such as program modules, being executed by one or more computers, such as client workstations, servers or other devices. Those skilled in the art will appreciate that the disclosed subject matter may be practiced with other computer system configurations and protocols.

FIG. 33 thus illustrates an example of a suitable computing system environment 3300a in which some aspects of the disclosed subject matter may be implemented, although as made clear above, the computing system environment 3300a is only one example of a suitable computing environment for a media device and is not intended to suggest any limitation as to the scope of use or functionality of the disclosed subject matter. Neither should the computing environment 3300a be interpreted as having any dependency or requirement relating to any one or combination of components illustrated in the exemplary operating environment 3300a.

With reference to FIG. 33, an exemplary remote device for implementing the disclosed subject matter includes a general purpose computing device in the form of a computer 3310a. Components of computer 3310a may include, but are not limited to, a processing unit 3320a, a system memory 3330a, and a system bus 3321a that couples various system components including the system memory to the processing unit 3320a. The system bus 3321a may be any of several types of bus structures including a memory bus or memory controller, a peripheral bus, and a local bus using any of a variety of bus architectures.

Computer 3310a typically includes a variety of computer readable media. Computer readable media can be any available media that can be accessed by computer 3310a. By way of example, and not limitation, computer readable media may comprise computer storage media and communication media. Computer storage media includes both volatile and nonvolatile, removable and non-removable media implemented in any method or technology for storage of information such as computer readable instructions, data structures, program modules or other data. Computer storage media includes, but is not limited to, RAM, ROM, EEPROM, flash memory or other memory technology, CDROM, digital versatile disks (DVD) or other optical disk storage, magnetic cassettes, magnetic tape, magnetic disk storage or other magnetic storage devices, or any other medium which can be used to store the desired information and which can be accessed by computer 3310a. Communication media typically embodies computer readable instructions, data structures, program modules or other data in a modulated data signal such as a carrier wave or other transport mechanism and includes any information delivery media.

The system memory 3330a may include computer storage media in the form of volatile and/or nonvolatile memory such as read only memory (ROM) and/or random access memory (RAM). A basic input/output system (BIOS), containing the basic routines that help to transfer information between elements within computer 3310a, such as during start-up, may be stored in memory 3330a. Memory 3330a typically also contains data and/or program modules that are immediately accessible to and/or presently being operated on by processing unit 3320a. By way of example, and not limitation, memory 3330a may also include an operating system, application programs, other program modules, and program data.

The computer 3310a may also include other removable/non-removable, volatile/nonvolatile computer storage media. For example, computer 3310a could include a hard disk drive that reads from or writes to non-removable, nonvolatile magnetic media, a magnetic disk drive that reads from or writes to a removable, nonvolatile magnetic disk, and/or an optical disk drive that reads from or writes to a removable, nonvolatile optical disk, such as a CD-ROM or other optical media. Other removable/non-removable, volatile/nonvolatile computer storage media that can be used in the exemplary operating environment include, but are not limited to, magnetic tape cassettes, flash memory cards, digital versatile disks, digital video tape, solid state RAM, solid state ROM and the like. A hard disk drive is typically connected to the system bus 3321a through a non-removable memory interface such as an interface, and a magnetic disk drive or optical disk drive is typically connected to the system bus 3321a by a removable memory interface, such as an interface.

A user may enter commands and information into the computer 3310a through input devices such as a keyboard and pointing device, commonly referred to as a mouse, trackball or touch pad. Other input devices may include a microphone, joystick, game pad, satellite dish, scanner, wireless device keypad, voice commands, or the like. These and other input devices are often connected to the processing unit 3320a through user input 3340a and associated interface(s) that are coupled to the system bus 3321a, but may be connected by other interface and bus structures, such as a parallel port, game port or a universal serial bus (USB). A graphics subsystem may also be connected to the system bus 3321a. A monitor or other type of display device is also connected to the system bus 3321a via an interface, such as output interface 3350a, which may in turn communicate with video memory. In addition to a monitor, computers may also include other peripheral output devices such as speakers and a printer, which may be connected through output interface 3350a.

The computer 3310a may operate in a networked or distributed environment using logical connections to one or more other remote computers, such as remote computer 3370a, which may in turn have media capabilities different from device 3310a. The remote computer 3370a may be a personal computer, a server, a router, a network PC, a peer device, personal digital assistant (PDA), cell phone, handheld computing device, or other common network terminal, or any other remote media consumption or transmission device, and may include any or all of the elements described above relative to the computer 3310a. The logical connections depicted in FIG. 33 include a network 3371a, such local area network (LAN) or a wide area network (WAN), but may also include other networks/buses, either wired or wireless. Such networking environments are commonplace in homes, offices, enterprise-wide computer networks, intranets and the Internet.

When used in a LAN networking environment, the computer 3310a is connected to the LAN 3371a through a network interface or adapter. When used in a WAN networking environment, the computer 3310a typically includes a communications component, such as a modem, or other means for establishing communications over the WAN, such as the Internet. A communications component, such as a modem, which may be internal or external, may be connected to the system bus 3321a via the user input interface of input 3340a, or other appropriate mechanism. In a networked environment, program modules depicted relative to the computer 2010a, or portions thereof, may be stored in a remote memory storage device. It will be appreciated that the network connections shown and described are exemplary and other means of establishing a communications link between the computers may be used.

While the disclosed subject matter has been described in connection with the preferred embodiments of the various figures, it is to be understood that other similar embodiments may be used or modifications and additions may be made to the described embodiment for performing the same function of the disclosed subject matter without deviating therefrom. For example, one skilled in the art will recognize that the disclosed subject matter as described in the present application applies to communication systems using the disclosed decoder techniques, systems, and methods and may be applied to any number of devices connected via a communications network and interacting across the network, either wired, wirelessly, or a combination thereof. In addition, it is understood that in various network configurations, access points may act as terminals and terminals may act as access points for some purposes.

Accordingly, while words such as transmitted and received are used in reference to the described communications processes; it should be understood that such transmitting and receiving is not limited to digital communications systems, but could encompass any manner of sending and receiving data suitable for processing by the described decoding techniques. For example, the data subject to the decoder techniques may be sent and received over any type of communications bus or medium capable of carrying the subject data from any source capable of transmitting such data. As a result, the disclosed subject matter should not be limited to any single embodiment, but rather should be construed in breadth and scope in accordance with the appended claims.

The word “exemplary” is used herein to mean serving as an example, instance, or illustration. For the avoidance of doubt, the subject matter disclosed herein is not limited by such examples. In addition, any aspect or design described herein as “exemplary” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, for the avoidance of doubt, such terms are intended to be inclusive in a manner similar to the term “comprising” as an open transition word without precluding any additional or other elements.

Various implementations of the disclosed subject matter described herein may have aspects that are wholly in hardware, partly in hardware and partly in software, as well as in software. Furthermore, aspects may be fully integrated into a single component, be assembled from discrete devices, or implemented as a combination suitable to the particular application and is a matter of design choice. As used herein, the terms “terminal,” “access point,” “component,” “system,” and the like are likewise intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on computer and the computer can be a component. One or more components may reside within a process and/or thread of execution and a component may be localized on one computer and/or distributed between two or more computers.

Thus, the systems of the disclosed subject matter, or certain aspects or portions thereof, may take the form of program code (e.g., instructions) embodied in tangible media, such as floppy diskettes, CD-ROMs, hard drives, or any other machine-readable storage medium, wherein, when the program code is loaded into and executed by a machine, such as a computer, the machine becomes an apparatus for practicing the disclosed subject matter. In the case of program code execution on programmable computers, the computing device generally includes a processor, a storage medium readable by the processor (including volatile and non-volatile memory and/or storage elements), at least one input device, and at least one output device.

Furthermore, the some aspects of the disclosed subject matter may be implemented as a system, method, apparatus, or article of manufacture using standard programming and/or engineering techniques to produce software, firmware, hardware, or any combination thereof to control a computer or processor based device to implement aspects detailed herein. The terms “article of manufacture”, “computer program product” or similar terms, where used herein, are intended to encompass a computer program accessible from any computer-readable device, carrier, or media. For example, computer readable storage media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick). Additionally, it is known that a carrier wave can be employed to carry computer-readable electronic data such as those used in transmitting and receiving electronic mail or in accessing a network such as the Internet or a local area network (LAN).

The aforementioned systems have been described with respect to interaction between several components. It can be appreciated that such systems and components can include those components or specified sub-components, some of the specified components or sub-components, and/or additional components, and according to various permutations and combinations of the foregoing. Sub-components can also be implemented as components communicatively coupled to other components rather than included within parent components, e.g., according to a hierarchical arrangement. Additionally, it should be noted that one or more components may be combined into a single component providing aggregate functionality or divided into several separate sub-components, and any one or more middle layers, such as a management layer, may be provided to communicatively couple to such sub-components in order to provide integrated functionality. Any components described herein may also interact with one or more other components not specifically described herein but generally known by those of skill in the art.

While for purposes of simplicity of explanation, methodologies disclosed herein are shown and described as a series of blocks, it is to be understood and appreciated that the claimed subject matter is not limited by the order of the blocks, as some blocks may occur in different orders and/or concurrently with other blocks from what is depicted and described herein. Where non-sequential, or branched, flow is illustrated via flowchart, it can be appreciated that various other branches, flow paths, and orders of the blocks, may be implemented which achieve the same or a similar result. Moreover, not all illustrated blocks may be required to implement the methodologies described hereinafter.

Furthermore, as will be appreciated various portions of the disclosed systems may include or consist of artificial intelligence or knowledge or rule based components, sub-components, processes, means, methodologies, or mechanisms (e.g., support vector machines, neural networks, expert systems, Bayesian belief networks, fuzzy logic, data fusion engines, classifiers . . . ). Such components, inter alia, can automate certain mechanisms or processes performed thereby to make portions of the systems and methods more adaptive as well as efficient and intelligent.

While the disclosed subject matter has been described in connection with the particular embodiments of the various figures, it is to be understood that other similar embodiments may be used or modifications and additions may be made to the described embodiment for performing the same function of the disclosed subject matter without deviating therefrom. Still further, the disclosed subject matter may be implemented in or across a plurality of processing chips or devices, and storage may similarly be effected across a plurality of devices. Therefore, the disclosed subject matter should not be limited to any single embodiment, but rather should be construed in breadth and scope in accordance with the appended claims.

What is claimed is:

1. A decoding method for a layered decoder having a current layer comprising a number of variable nodes and a next layer comprising a number of check nodes, the method comprising:
determining whether both of the current layer and the next layer have a non-null matrix at a column where the current layer overlaps the next layer creating an overlapped column;
computing an optimal decoding order of the layers; and
bypassing a memory write operation for the current layer and a memory read operation for the next layer based on the outcome of the determining or the computing.

2. The method of claim 1, further comprising scheduling at least one of the memory write operation or the memory read operation according to the optimal decoding order.

3. The method of claim 1, computing an optimal decoding order of the layers includes executing a search algorithm to compute the optimal decoding order.

4. The method of claim 3, executing a search algorithm includes at least one of executing a comprehensive algorithm, executing an algorithm that determines a path with maximum cost in an undirected graph that models the layered decoder, or executing an algorithm that utilizes a simulated annealing process to determine an optimal decoding order.

5. The method of claim 1, computing an optimal decoding order of the layers includes determining a decoupled order of sub-blocks to be updated within at least one of the layers.

6. The method of claim 5, the bypassing includes decoding the next layer directly using updated posterior reliability values of a variable node of the number of variable nodes of the current layer.

7. The method of claim 6, the determining a decoupled order of sub-blocks to be updated includes determining whether a memory write operation for a column of the current layer can occur concurrently with a read operation of a column of the next layer to create the overlapped column.

8. The method of claim 6, decoding the next layer directly includes generating two outgoing message magnitudes for a check node of the number of check nodes of the next layer from two of the incoming messages having smallest magnitudes for the variable node of the number of variable nodes of the current layer and a soft-input-soft-output unit generated index for the decoupled order of sub-blocks.

9. The method of claim of claim 8, the generating two outgoing message magnitudes includes using one of a min-sum approximation algorithm, an offset min-sum algorithm, or a two-output approximation algorithm to compute the two outgoing message magnitudes.

10. The method of claim 6, further comprising determining whether the updated posterior reliability values exceed a threshold value.

11. The method of claim 10, further comprising substituting the updated posterior reliability values with the threshold value in the decoding the next layer directly if it is determined that the updated posterior reliability values exceed the threshold value.

12. The method of claim 10, further comprising writing a bit to a threshold memory in lieu of the memory write operation for the current layer to indicate that the value of the updated posterior reliability values exceed the threshold value.

13. The method of claim 10, further comprising iteratively determining the threshold value based on a determined error-correction performance parameter, a specified error-correction performance parameter, a power usage requirement, a power reduction requirement, a power reduction performance parameter, or a power reduction scheme.

14. A decoding system comprising:
a channel Random Access Memory (RAM) that stores soft output values of a variable node of a current layer of two consecutive decoding layers in a layered decoder;
a memory bypass component that bypasses a memory write operation and a memory read operation for the channel RAM to directly pass the soft output values of the variable node when the two consecutive layers in the layered decoder have overlapping columns; and
a soft-input-soft-output (SISO) unit that computes a two-output approximation of a check node for a next layer of the two consecutive layers in the layered decoder based on either the soft output values stored in the channel RAM or the soft output values directly passed by the memory bypass component.

15. The system of claim 14, the memory bypass component further comprises a scheduling component that schedules a decoding order for the two consecutive layers in the decoder to maximize the number of overlapping columns between the two consecutive layers.

16. The system of claim 14, the SISO unit computes the two-output approximation based on one of a min-sum approximation algorithm, an offset min-sum algorithm, or a two-output approximation algorithm.

17. The system of claim 14, further comprising a thresholding component that determines whether the soft output values exceed a preset threshold, the thresholding component replaces the soft output values with the preset threshold prior to storage in the channel RAM if the soft output values exceed the preset threshold.

18. The system of claim 17, the thresholding component is configured to store a bit in a threshold memory to indicate that the soft output values exceed the preset threshold.

19. A layered decoding apparatus comprising:
a channel Random Access Memory (RAM) that stores soft output values of a variable node of a current layer of two consecutive decoding layers;
a plurality of pipeline registers coupled to an Add-array that facilitates bypassing the channel RAM read and write operations, the output of the Add-array comprises the soft output values, the determination to bypass channel RAM read and write operations is based on whether the current layer and a next layer of the two consecutive decoding layers have overlapping columns; and
a plurality of multiplexers that selectively passes the output of the Add-array and an output of the channel RAM based on the determination whether the channel RAM read and write operations are to be bypassed.

20. The layered decoding apparatus of claim 19, further comprising a soft-input-soft-output (SISO) unit that computes a two-output approximation of a check node for the next layer of the two consecutive decoding layers based on an output of the plurality of multiplexers.

21. The layered decoding apparatus of claim 20, the SISO unit calculates the two-output approximation according to one of a min-sum approximation algorithm, an offset min-sum algorithm, or a two-output approximation algorithm.

22. The layered decoding apparatus of claim 19, further comprising a threshold memory that stores a bit when the soft output values exceed a threshold value in lieu of writing the soft output values to the channel RAM.
